(19) United States
(12) Patent Application Publication
(10) Pub. No.: US 2026/0291476 A1
(43) Pub. Date: Sep. 24, 2026

(54) ELECTRONIC CIRCUITRY, POWER CONVERTER, AND SIGNAL TRANSMISSION METHOD

(71) Applicants: Kabushiki Kaisha Toshiba, Kawasaki-shi (JP); Toshiba Electronic Devices & Storage Corporation, Kawasaki-shi (JP)

(72) Inventors: Satoshi TAKAYA, Konosu Saitama (JP); Hiroaki ISHIHARA, Yokohama Kanagawa (JP)

(21) Appl. No.: 19/529,868

(22) Filed: Feb. 4, 2026

(30) Foreign Application Priority Data
Mar. 18, 2025 (JP) 2025-043865

(51) Int. Cl. H03K 5/04; H03K 5/24

(52) U.S. Cl. CPC H03K 5/04; H03K 5/24

(57) ABSTRACT

An electronic circuitry includes a first conversion circuit configured to convert a differential input signal into a first signal based on a first clock signal. A first electromagnetic field coupler transmits the first signal received at a first terminal to a second terminal as a second signal via an isolation element including a capacitance. A second conversion circuit converts the second signal into an output signal based on the first clock signal. A first charge and discharge circuit charges or discharges the capacitance from at least one of the terminals in response to a fluctuation in a voltage of a direct current component of the first signal to suppress a fluctuation of a voltage of a direct current component of the second signal.

### CROSS REFERENCE TO RELATED APPLICATIONS

This application is based upon and claims the benefit of priority from the prior Japanese Patent Application No. 2025-043865, filed on Mar. 18, 2025, the entire contents of which are incorporated herein by reference.

### FIELD

The present embodiment relates to an electronic circuitry, a power converter, and a signal transmission method.

### BACKGROUND

In a signal transmission via an isolation barrier, an isolation element such as a capacitor is used as the isolation barrier. In a case where the capacitor is used as the isolation element, through a capacitance of the capacitor itself and a parasitic capacitance between a primary (high voltage) side and a secondary (low voltage) side, a fluctuation of a common mode voltage on the primary side is transmitted to the secondary side. As a result, a signal potential on the secondary side exceeds input and output ranges of a circuit and a reference potential such as a power supply potential, and an accurate output is not obtained. With this configuration, a common mode characteristic of an output on the secondary side represented by an indicator such as a common mode transient immunity (CMTI) deteriorates. In addition, in a case where a common mode rejection ratio (CMRR) of an amplifier is low, an input differential signal is converted into a common mode signal, and a correct voltage is not output.

An example of a measure for improving the common mode characteristic includes a measure to adopt a circuit which balances a voltage at a signal node on a reception side. Since the voltage balancing circuit is arranged on the secondary side relative to an isolator, an input parasitic capacitance on the reception side increases. Due to this parasitic capacitance, an original signal amplitude may attenuate, and a signal characteristic such as a signal-to-noise ratio (SNR) may degrade. Furthermore, this circuit is effective in a case where a slew rate of the common mode voltage is low, but for a CMTI countermeasure of several tens of kV/μs, current supply at several mA to several tens of mA is required. When a transistor sufficiently large to deal with this is to be regularly turned on, there is a concern that at the time of a normal operation, an input impedance excessively falls.

### BRIEF DESCRIPTION OF THE DRAWINGS

FIG. 1 illustrates a configuration example of an isolation amplifier as an electronic circuitry according to the present embodiment;

FIG. 2 schematically illustrates input analog signals;

FIG. 3 illustrates an example of clock signals;

FIG. 4 illustrates an example of a generated high frequency signal;

FIGS. 5A to 5C illustrate configuration examples of an electromagnetic field coupler;

FIG. 6 illustrates a configuration example of a potential fluctuation detector and a charge and discharge circuit;

FIG. 7 illustrates a configuration example of an isolation amplifier according to a comparative example;

FIG. 8 illustrates an operation example in a case where a common mode voltage on a primary side steeply rises in the comparative example of FIG. 7;

FIGS. 9A to 9C are supplementary explanatory diagrams of FIG. 8;

FIG. 10 is a diagram for describing that a potential on a secondary side fluctuates due to a fluctuation of the common mode voltage on the primary side, and a normal output is obtained;

FIG. 11 is a diagram in which a graph of an input signal is added to FIG. 8;

FIG. 12 illustrates an operation example in a case where the common mode voltage on the primary side steeply rises in the configuration example of FIG. 1;

FIGS. 13A to 13C are supplementary explanatory diagrams of FIG. 12;

FIG. 14 illustrates an operation example in a case where the common mode voltage on the primary side steeply falls in the configuration of the comparative example of FIG. 7;

FIGS. 15A to 15C are supplementary explanatory diagrams of FIG. 14;

FIG. 16 illustrates an operation example in a case where the common mode voltage on the primary side steeply falls in the configuration example of FIG. 1;

FIGS. 17A to 17C are supplementary explanatory diagrams of FIG. 16;

FIG. 18 illustrates an example in which protection circuits are added to the configuration of FIG. 1;

FIG. 19 illustrates an isolation amplifier according to a second embodiment;

FIG. 20 illustrates a connection example between the isolation amplifier and peripheral circuits including gate drivers;

FIG. 21 illustrates a configuration example of a control circuit;

FIG. 22 is a timing chart illustrating an operation example of the control circuit;

FIG. 23 illustrates an isolation amplifier according to a third embodiment;

FIG. 24 illustrates an isolation amplifier according to a fourth embodiment;

FIG. 25 illustrates an isolation amplifier according to a fifth embodiment;

FIG. 26 illustrates an operation example in a case where the common mode voltage on the primary side steeply rises in a configuration example of FIG. 25;

FIGS. 27A to 27C are supplementary explanatory diagrams of FIG. 26;

FIG. 28 illustrates an operation example in a case where the common mode voltage on the primary side steeply falls in the configuration example of FIG. 25;

FIGS. 29A to 29C are supplementary explanatory diagrams of FIG. 28; and

FIG. 30 illustrates a configuration example of a power converter according to a sixth embodiment.

### DETAILED DESCRIPTION

According to one embodiment, an electronic circuitry includes a first conversion circuit configured to convert an input signal into a first signal having a frequency according to a first clock signal, the input signal being a differential signal; a first electromagnetic field coupler having a first terminal and a second terminal, and configured to transmit the first signal received at the first terminal to the second terminal as a second signal via a first isolation element including a capacitance; a second conversion circuit configured to convert the second signal into an output signal having a frequency according to the input signal based on the first clock signal; and a first charge and discharge circuit configured to charge or discharge the capacitance of the first electromagnetic field coupler from at least one of the first terminal and the second terminal in response to a voltage of a direct current component of the first signal fluctuating, to suppress a fluctuation of a voltage of a direct current component of the second signal.

Hereinafter embodiments of the present invention will be described with reference to the drawings.

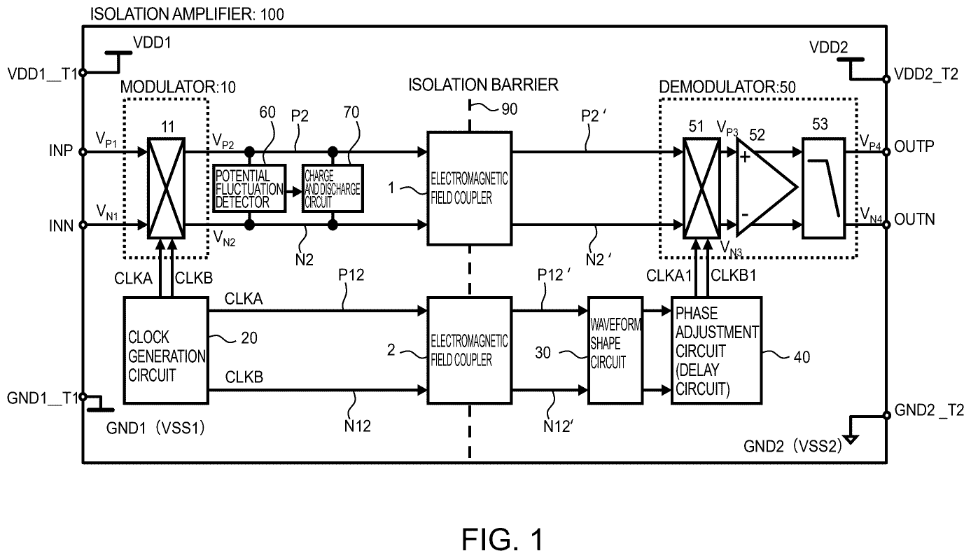

FIG. 1 illustrates a configuration example of an isolation amplifier 100 as an electronic circuitry according to the present embodiment. The isolation amplifier 100 is a circuit configured to transmit analog signals, which are input signals being differential supplied to an input side, to an output side via an isolation barrier 90. In the following descriptions, when the isolation barrier 90 is set as a boundary, the input side (left side of the drawing) of the analog signals is denoted as a primary side, and the output side (right side of the drawing) of the analog signals is denoted as a secondary side. For example, the primary side is a high voltage side, and the secondary side is a low voltage side.

Respectively independent reference potentials GND1 and GND2 and power supply potentials VDD1 and VDD2 are used in the primary side and the secondary side. Terminals GND_T1 and GND_T2 to which the reference potentials GND1 and GND2 are supplied are provided in the primary side and the secondary side. Terminals VDD_T1 and VDD_T2 to which the power supply potentials VDD1 and VDD2 are supplied are also provided in the primary side and the secondary side.

An input terminal INP and an input terminal INN to which analog signals to be transmitted to the secondary side are input are provided in the primary side. When the input terminal INP and the input terminal INN are respectively connected to one terminal and another terminal in an element serving as a measurement target, for example, voltage signals at the one terminal and the other terminal are input as analog signals V_{P1} and V_{N1}. In other words, voltages are respectively input to the input terminal INP and the input terminal INN from the one terminal and the other terminal of the element. The input analog signals have any waveforms from several tens of Hz to several tens of MHz, for example. As an example, the element is a transistor, a resistor, or the like. The analog signals that have been input are input to a modulator 10 (first conversion circuit).

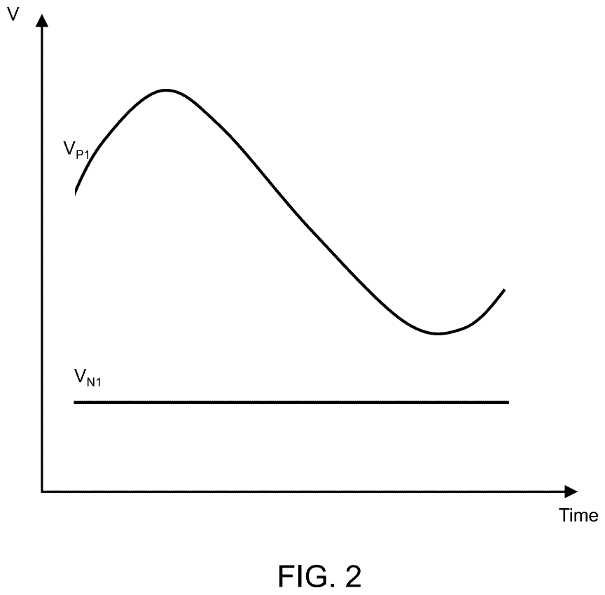

FIG. 2 schematically illustrates the analog signals V_{P1} and V_{N1} (input signals) input to the input terminal INP and the input terminal INN. The analog signals V_{P1} and V_{N1} are input signals of the isolation amplifier 100. A difference between the analog signals V_{P1} and V_{N1} (amplitude of the input signals) represents a voltage of the element serving as the measurement target, for example.

A clock generation circuit 20 generates clock signals CLKA and CLKB. The clock generation circuit 20 supplies the clock signals CLKA and CLKB to the modulator 10 and also transmits the clock signals CLKA and CLKB to the secondary side via an electromagnetic field coupler 2 (second electromagnetic field coupler). The clock signals are rectangular waves at several hundreds of MHz, for example.

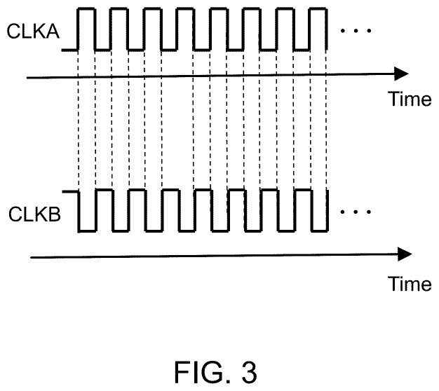

FIG. 3 illustrates examples of the clock signals CLKA and CLKB. The clock signals CLKA and CLKB are signals including periodic rectangular pulses. The clock signals CLKA and CLKB are differential clock signals. That is, CLKB is a signal obtained by inverting CLKA. When CLKA is High level, CLKB is Low level, and when CLKA is Low level, CLKB is High level. Periods (frequencies) of the clock signals CLKA and CLKB are the same and are, for example, several hundreds of MHz. Amplitudes of the clock signals CLKA and CLKB are the same or substantially the same.

The modulator 10 is the first conversion circuit configured to increase frequencies of the input analog signals (conversion into high frequencies). For the analog signals, a frequency converter 11 may be referred to as a mixer, a chopper, a sampling circuit, or the like. The modulator 10 includes the frequency converter 11. An amplifier may be arranged in a stage preceding the frequency converter 11.

The frequency converter 11 performs conversion of the analog signals V_{P1} and V_{N1} (input signals) input from the input terminals INP and INN into high frequencies based on the clock signals CLKA and CLKB supplied from the clock generation circuit 20. That is, the frequency converter 11 converts the analog signals V_{P1} and V_{N1} according to periods (frequencies) of the clock signals CLKA and CLKB to generate high frequency signals V_{P2} and V_{N2}. The high frequency signals V_{P2} and V_{N2} have frequencies according to the clock signals CLKA and CLKB. In the present embodiment, the conversion of the signals into the high frequencies based on the clock signals in the above-described manner is referred to as modulation of the signals. The high frequency signals V_{P2} and V_{N2} are output to an electromagnetic field coupler 1 (first electromagnetic field coupler). The high frequency signals V_{P2} and V_{N2} correspond to first signals generated by converting the frequencies of the input signals. The first signals have frequencies according to first clock signals.

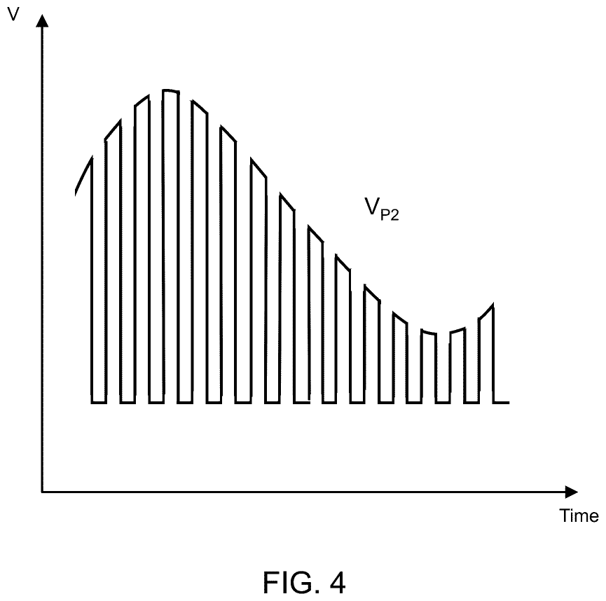

FIG. 4 illustrates an example of the generated high frequency signal V_{P2}. When the analog signals V_{P1} and V_{N1} are mutually sampled according to the clock signals CLKA and CLKB, the high frequency signal V_{P2} is generated. In a similar manner, the high frequency signal V_{N2} is generated when the analog signals V_{N1} and V_{P1} are mutually sampled according to the clock signals CLKA and CLKB.

The electromagnetic field coupler 1 is an isolation element (first isolation element) including capacitances. The electromagnetic field coupler 1 is a transmitter configured to isolate the primary side and the secondary side and transmit the high frequency signals V_{P2} and V_{N2} input from the modulator 10 to the secondary side via the isolation. The electromagnetic field coupler 1 includes, for example, capacitors, transformers, or the like. When the high frequency signals are transmitted from the primary side to the secondary side, phases shift (fluctuate) with respect to the signals input to the electromagnetic field coupler 1 due to a characteristic of the electromagnetic field coupler 1. Capacitances (which also include a case of parasitic capacitances) exist between the primary side and the secondary side of the electromagnetic field coupler 1. The electromagnetic field coupler 1 has first terminals on the primary side and second terminals on the secondary side. The electromagnetic field coupler 1 transmits the first signals that are input to the first terminals to the second terminals by electromagnetic field coupling and outputs the transmitted signals as the second signals.

The electromagnetic field coupler 2 is an isolation element (second isolation element) including capacitances. The electromagnetic field coupler 2 is a transmitter configured to isolate the primary side and the secondary side and transmit the clock signals CLKA and CLKB input from the clock generation circuit 20 to the secondary side via the isolation. The electromagnetic field coupler 2 includes, for example, capacitors, transformers, or the like. When the clock signals are transmitted from the primary side to the secondary side, phases shift with respect to the signals input to the electromagnetic field coupler 2 due to a characteristic of the electromagnetic field coupler 2. Capacitances (which also include a case of parasitic capacitances) exist between the primary side and the secondary side of the electromagnetic field coupler 2. The electromagnetic field coupler 2 has third terminals on the primary side and fourth terminals on the secondary side. The electromagnetic field coupler 2 transmits the first clock signals, which are clock signals input from the clock generation circuit 20 to the third terminals, to the fourth terminals by electromagnetic field coupling to be output as second clock signals.

In the present embodiment, a configuration of the electromagnetic field coupler 2 is the same as that of the electromagnetic field coupler 1. With this configuration, phase shift amounts (phase delay amounts) generated in the electromagnetic field couplers 1 and 2 can be set to be the same or substantially the same. It is noted however that it is not excluded to respectively use different configurations in the electromagnetic field couplers 1 and 2.

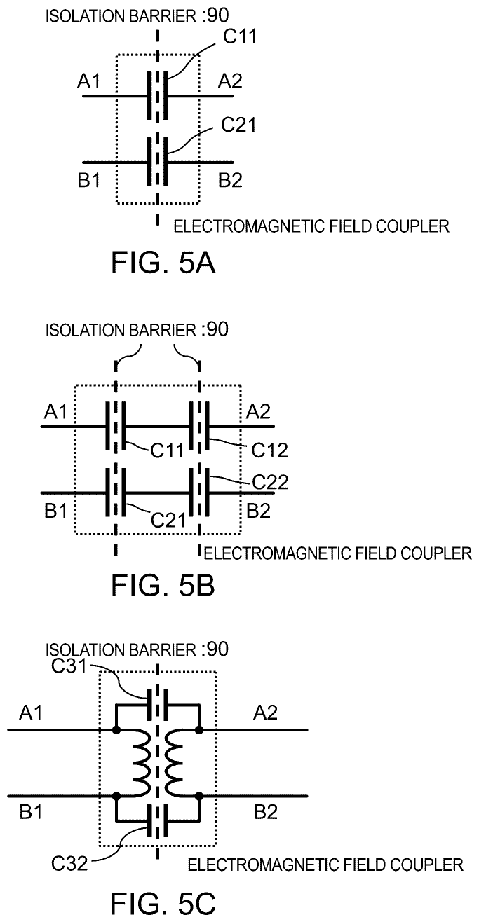

FIGS. 5A to 5C illustrate configuration examples of the electromagnetic field coupler 1. A configuration of the electromagnetic field coupler 2 is similar to that of the electromagnetic field coupler 1.

FIG. 5A illustrates a first configuration example of the electromagnetic field coupler 1. The electromagnetic field coupler 1 includes terminals A1 and B1 on the primary side and terminals A2 and B2 on the secondary side. The high frequency signal V_{P2} is input to the terminal A1, and the high frequency signal V_{N2} is input to the terminal B1. A single capacitor C11 is provided between the terminal A1 and the terminal A2. The high frequency signal V_{P2} input to the terminal A1 is transmitted to the terminal A2 on the output side via the capacitor C11. A single capacitor C21 is provided between the terminal B1 and the terminal B2. The high frequency signal V_{N2} input to the terminal B1 is transmitted to the terminal B2 on the output side via the capacitor C21. The capacitors C11 and C21 function as isolation barriers that isolate the input side and the output side. More specifically, a dielectric portion (isolator), for example, a silicon oxide film, a polyimide film, or the like, between two opposing planar plates of the capacitor functions as the isolation barrier. Capacitances of the capacitors C11 and C21 are the same as an example, but mutually different configurations can also be adopted.

FIG. 5B illustrates a second configuration example of the electromagnetic field coupler 1. A plurality of capacitors C11 and C12 that are connected in series are provided between the terminal A1 and the terminal A2. A plurality of capacitors C21 and C22 that are connected in series are provided between the terminal B1 and the terminal B2. The capacitors C11, C12, C21, and C22 function as isolation barriers that isolate the input side and the output side. In the case of the single capacitor as in FIG. 5A, when the capacitor undergoes dielectric breakdown, there is a possibility of electrical conduction between the primary side and the secondary side. By connecting the capacitors in series in a multiple configuration, even in a case where one among the plurality of capacitors undergoes dielectric breakdown, isolation is maintained. With this configuration, safety can be improved. Capacitances of the capacitors C11 and C21 are the same as an example, but mutually different configurations can also be adopted. Capacitances of the capacitors C12 and C22 are the same as an example, but mutually different configurations can also be adopted.

FIG. 5A and FIG. 5B illustrate the configuration examples in which the capacitors are used as the configuration of the electromagnetic field coupler 1, but a configuration in which other isolation elements such as transformers are used can also be adopted.

FIG. 5C illustrates an example in which a transformer is used as a configuration of the electromagnetic field coupler 1. A winding W1 on the primary side faces a winding W2 on the secondary side. A dielectric between the windings W1 and W2 functions as an isolation barrier. Parasitic interwinding capacitances C31 and C32 exist between the windings W1 and W2.

A waveform shape circuit 30 shapes the clock signals CLKA and CLKB (second clock signals) transmitted via the electromagnetic field coupler 2. Amplitudes of the clock signals received on the secondary side via the electromagnetic field coupler 2 fluctuate (for example, attenuate) due to the characteristic of the electromagnetic field coupler 2. The waveform shape circuit 30 adjusts (shapes) the amplitudes of the transmitted clock signals to match the amplitudes of the clock signals used in the secondary side.

For example, the amplitudes of the clock signals received on the secondary side are amplified so as to be the same amplitudes as those of the clock signals generated by the clock generation circuit 20. In this case, the waveform shape circuit 30 includes an amplifier configured to amplify the amplitudes of the clock signals received on the secondary side. Alternatively, in a case where the amplitudes of the clock signals used in the secondary side are small, the waveform shape circuit 30 may be a circuit configured to clip the amplitudes of the clock signals received on the secondary side.

A phase adjustment circuit 40 adjusts the phases of the clock signals which are shaped by the waveform shape circuit 30 and supplies the clock signals to a demodulator 50. The clock signals after the phase adjustments are, for example, rectangular waves at several hundreds of MHz.

The phase adjustment circuit 40 is configured by a delay circuit, for example. A reason why the adjustment is performed by the phase adjustment circuit 40 will be described. When waveforms of the clock signals CLKA and CLKB are shaped by the waveform shape circuit 30, phase delays occur. For this reason, the phases of the clock signals CLKA and CLKB are delayed with respect to the high frequency signals V_{P2} and V_{N2} transmitted via the electromagnetic field coupler 1. In view of the above, by adjusting (compensating) the phases of the clock signals CLKA and CLKB by the amounts corresponding to the delays, the phases of the clock signals CLKA and CLKB are caused to match those of the high frequency signals V_{P2} and V_{N2}. The clock signals CLKA1 and CLKB1 after the phase adjustments are input to the demodulator 50.

The demodulator 50 includes a frequency converter (mixer) 51, an amplifier 52, and a low pass filter (LPF) 53. The demodulator 50 is a second conversion circuit configured to convert frequencies of the high frequency signals (first signals) input from the electromagnetic field coupler 1 based on the clock signals after the phase adjustments (conversion into low frequencies) which are input from the phase adjustment circuit 40. With this configuration, the demodulator 50 generates output signals which have frequencies according to the input signals. In the present embodiment, the conversion into the low frequencies based on the clock signal that are input is referred to as demodulation of the signals. The output signals of the demodulator 50 correspond to analog signals (restored signals) in which the high frequency signals input to the demodulator 50 have been restored to approximately the same frequencies as those of the original input signals. Hereinafter, the demodulator 50 will be described in detail.

The frequency converter 51 converts (demodulates) the high frequency signals V_{P2} and V_{N2} input via the electromagnetic field coupler 1 based on the clock signals CLKA1 and CLKB1 after the phase adjustments which are input from the phase adjustment circuit 40. With this configuration, analog signals V_{P3} and V_{N3} having frequencies according to the input signals are generated. For example, the analog signals V_{P3} and V_{N3} are generated by sampling the high frequency signals V_{P2} and V_{N2} in mutually opposite directions based on the clock signals CLKA1 and CLKB1.

The amplifier 52 amplifies the analog signals V_{P3} and V_{N3} converted by the frequency converter 51 to be output to the low pass filter 53.

The low pass filter 53 causes high frequency components (high frequency components included in the clock signals CLKA1 and CLKB1 and the high frequency signals V_{P2} and V_{N2}) to attenuate or decrease from the amplified analog signals V_{P3} and V_{N3}. With this configuration, analog signals V_{P4} and V_{N4} serving as output signals are generated. The low pass filter 53 outputs the analog signals V_{P4} and V_{N4} from an output terminal OUTP and an output terminal OUTN. The analog signals V_{P3} and V_{N3} have frequencies corresponding to the input signals (analog signals V_{P1} and V_{N1}).

The modulator 10, the clock generation circuit 20, the waveform shape circuit 30, the phase adjustment circuit 40, and the demodulator 50 of FIG. 1 may be configured by a circuit such as an application specific integrated circuit (ASIC) or a field-programmable gate array (FPGA) or a processor. Alternatively, some or all of these elements may be executed by a central processing unit (CPU) configured to execute a program.

A potential fluctuation detector 60 (first detection circuit) and a charge and discharge circuit 70 (first charge and discharge circuit) are connected between the modulator 10 on the primary side and the electromagnetic field coupler 1. The potential fluctuation detector 60 detects a fluctuation of a common mode voltage of the output signals (first signals) from the modulator 10. The common mode voltage is equivalent to a voltage of direct current components of the differential signals (herein, the first signals) or an average voltage with respect to the reference potential. The charge and discharge circuit 70 charges or discharges the capacitances included in the electromagnetic field coupler 1 from the terminals on the primary side of the electromagnetic field coupler 1 according to a detection result. With this configuration, when the common mode voltage of the first signal fluctuates due to fluctuations of the power supply potential and the reference potential on the primary side, a fluctuation of a common mode voltage of signals (second signals) output from the terminals on the secondary side of the electromagnetic field coupler 1 is suppressed. Hereinafter, this will be described in further detail.

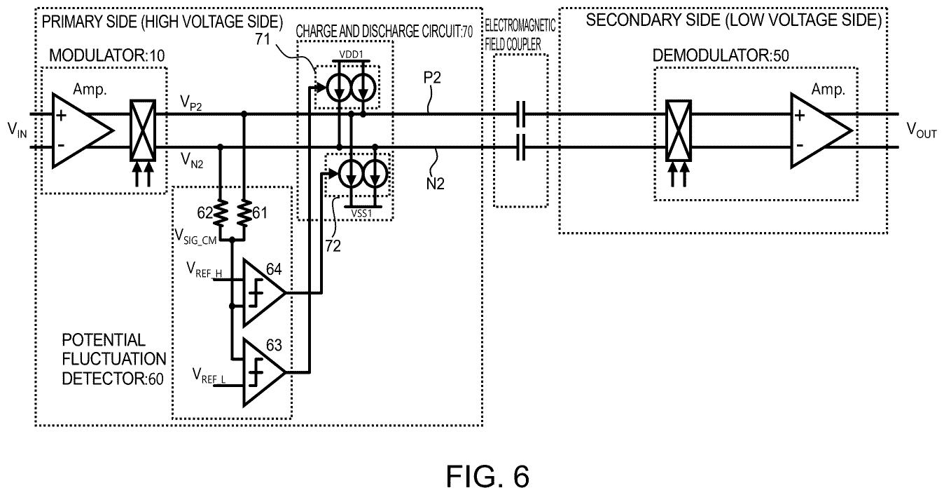

FIG. 6 illustrates a configuration example of the potential fluctuation detector 60 and the charge and discharge circuit 70.

The potential fluctuation detector 60 measures the high frequency signals V_{P2} and V_{N2} and detects a fluctuation of the common mode voltage of the high frequency signals V_{P2} and V_{N2} (or the common mode voltage of the analog signals V_{P1} and V_{N1}). The potential fluctuation detector 60 includes a resistor 61 one terminal of which is connected to a signal line (signal line P2) of the high frequency signal V_{P2}, a resistor 62 one terminal of which is connected to a signal line (signal line N2) of the analog signal V_{N1}, and the other terminals of the resistors 61 and 62 are connected to each other. A voltage at a connection point at which the other terminals are connected to each other is obtained as a common mode voltage (V_{SIG_CM}). The common mode voltage (V_{SIG_CM}) is an average voltage of the two high frequency signals V_{P2} and V_{N2}. The signal lines P2 and N2 correspond to first signal lines through which the first signals are transmitted.

The potential fluctuation detector 60 includes a comparator 63 (first comparator) configured to compare the common mode voltage (V_{SIG_CM}) with a reference voltage (V_{REF_L}), and a comparator 64 (second comparator) configured to compare the common mode voltage (V_{SIG_CM}) with a reference voltage (V_{REF_H}). The comparators 63 and 64 output comparison result signals to the charge and discharge circuit 70. Herein, V_{REF_L} <V_{REF_H}. For example, when the assumed common mode voltage (V_{SIG_CM}) is 2.5 V, the reference voltage (V_{REF_L}) is 2.4 V +VSS1 (voltage obtained by adding 2.4 V to VSS1), and the reference voltage (V_{REF_H}) is 2.6 V +VSS1 (voltage obtained by adding 2.6 V to VSS1). The reference voltage (V_{REF_L}) corresponds to a first reference voltage that is a sum of the reference potential of the first signals and a first predetermined value, and the reference voltage (V_{REF_H}) corresponds to a second reference voltage that is a sum of the reference potential and a second predetermined value that is greater than the first predetermined value.

In a case where V_{SIG_CM} is less than V_{REF_L}, that is, in the case of V_{SIG_CM}<V_{REF_L}, the comparator 63 (first comparator) outputs, as a first comparison result signal, a drive signal to instruct a charge circuit 71 in the charge and discharge circuit 70 to perform charging. In the case of V_{SIG_CM}>V_{REF_L}, the comparator 63 outputs a non-drive signal to instruct the charge circuit 71 in the charge and discharge circuit 70 not to perform charging. As an example, the drive signal is a high level signal, and the non-drive signal is a low level signal, but a relationship between the signals may be reversed.

In a case where V_{SIG_CM} is greater than V_{REF_H}, that is, in the case of V_{REF_H}<V_{SIG_CM}, the comparator 64 (second comparator) outputs, as a second comparison result signal, a drive signal to instruct a discharge circuit 72 in the charge and discharge circuit 70 to perform discharging. In the case of V_{REF_H}>V_{SIG_CM}, the comparator 64 outputs a non-drive signal to instruct the discharge circuit 72 not to perform discharging. As an example, the drive signal is a high level signal, and the non-drive signal is a low level signal, but a relationship between the signals may be reversed.

Therefore, in the case of V_{SIG_CM}<V_{REF_L}, the charge circuit 71 in the charge and discharge circuit 70 performs charging. In a case where V_{SIG_CM} is greater than or equal to V_{REF_L} and is less than or equal to V_{REF_H} (in the case of V_{REF_L}=<V_{SIG_CM}=<V_{REF_H}), both the charge circuit 71 and the discharge circuit 72 in the charge and discharge circuit 70 perform neither charging nor discharging. In the case of V_{REF_H}<V_{SIG_CM}, the discharge circuit 72 in the charge and discharge circuit 70 performs discharging.

The charge and discharge circuit 70 includes the charge circuit 71 and the discharge circuit 72. The charge circuit 71 includes current sources respectively connected between the power supply potential VDD1 and the signal line P2 and the signal line N2. Instead of the current sources, switches may be used. The charge circuit 71 is driven based on the comparison result signal that is the output of the comparator 63. At the time of charging, by supplying currents to the signal line P2 and the signal line N2, the charge circuit 71 performs charging electric charges to the capacitances included in the electromagnetic field coupler from terminals of the electromagnetic field coupler 1 which are connected to the signal line P2 and the signal line N2.

In addition, the discharge circuit 72 includes current sources respectively connected between the signal line P2 and the signal line N2 and a ground VSS1 serving as the reference potential. Instead of the current sources, switches may be used. At the time of discharging, by extracting the electric charges (current) of the capacitances included in the electromagnetic field coupler 1 from the terminals of the electromagnetic field coupler which are connected to the signal line P2 and the signal line N2, the discharge circuit 72 performs discharging of the capacitances.

In the case of V_{SIG_CM}<V_{REF_L}, following the comparison result signal of the comparator 63, the charge circuit 71 is driven (charging is ON, and discharging is OFF). In the case of V_{REF_H}<V_{SIG_CM}, following the comparison result signal of the comparator 64, the discharge circuit 72 is driven (charging is OFF, and discharging is ON). In the case of V_{REF_L} <V_{SIG_CM} <V_{REF_H}, both the charge circuit 71 and the discharge circuit 72 are not driven (charging is OFF, and discharging is OFF).

In this manner, when the potential fluctuation detector 60 and the charge and discharge circuit 70 operate, even in a case where the common mode voltage on the primary side steeply fluctuates, charging and discharging of the signal line P2 and the signal line N2 are performed, and transmission of the fluctuation of the common mode voltage from the primary side to the secondary side is suppressed. With this configuration, a CMTI immunity is improved as a whole.

Hereinafter, a specific operation example will be described. Both a case where the common mode voltage on the primary side steeply rises and a case where the common mode voltage on the primary side steeply falls will be described.

### Case Where Common Mode Voltage on Primary Side Steeply Rises

To deepen understanding, first, as a comparative example, by using a circuit configuration obtained by removing the potential fluctuation detector 60 and the charge and discharge circuit 70 from the configuration of FIG. 1, an operation example in which the common mode voltage on the primary side steeply rises will be described.

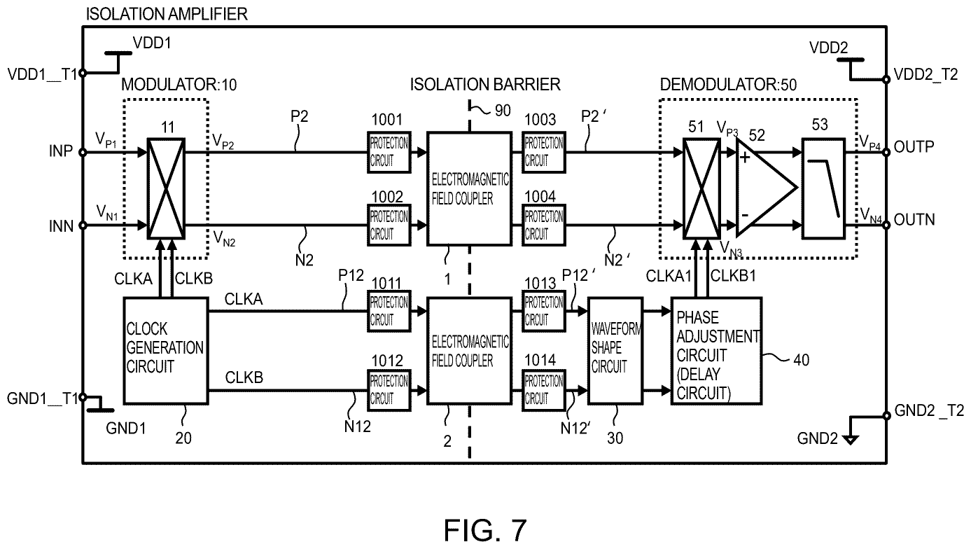

FIG. 7 illustrates a configuration example of an isolation amplifier according to the comparative example. As compared with the configuration of FIG. 1, the potential fluctuation detector 60 and the charge and discharge circuit 70 are removed. It is noted however that protection circuits 1001 to 1004 and 1011 to 1014 are added. The protection circuits 1001 and 1002 are respectively provided to a signal line P1 and a signal line N1 which are connected to the terminals on the primary side of the electromagnetic field coupler 1. The protection circuits 1003 and 1004 are respectively provided to a signal line P1′ and a signal line N1′ which are connected to the terminals on the secondary side. The protection circuits 1011 and 1012 are respectively provided to a signal line P12 and a signal line N12 which are connected to the terminals on the primary side of the electromagnetic field coupler 2. The protection circuits 1013 and 1014 are respectively provided to a signal line P12′ and a signal line N12′ which are connected to the terminals on the secondary side.

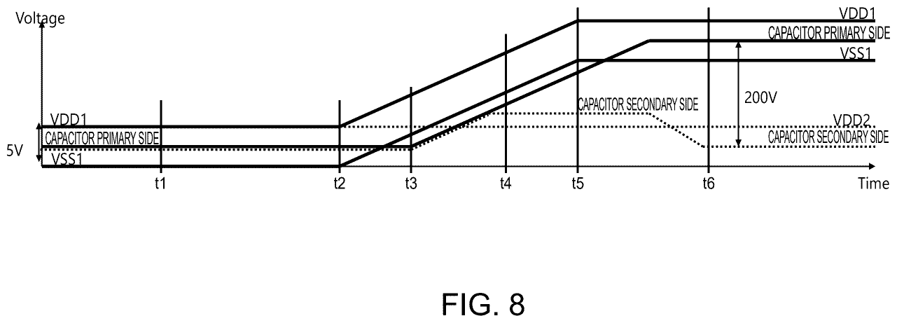

FIG. 8 illustrates an operation example in a case where the common mode voltage on the primary side steeply rises in the configuration of the comparative example of FIG. 7. A horizontal axis represents time, and a vertical axis represents a voltage. Herein, for simplicity, a state in which signal transmission is not performed is assumed. A graph of VDD1, a graph of VSS1, a graph of the common mode voltage on the primary side (graph of a “capacitor primary side”), a graph of VDD2, and a graph of the common mode voltage on the secondary side (graph of a “capacitor secondary side”) are illustrated.

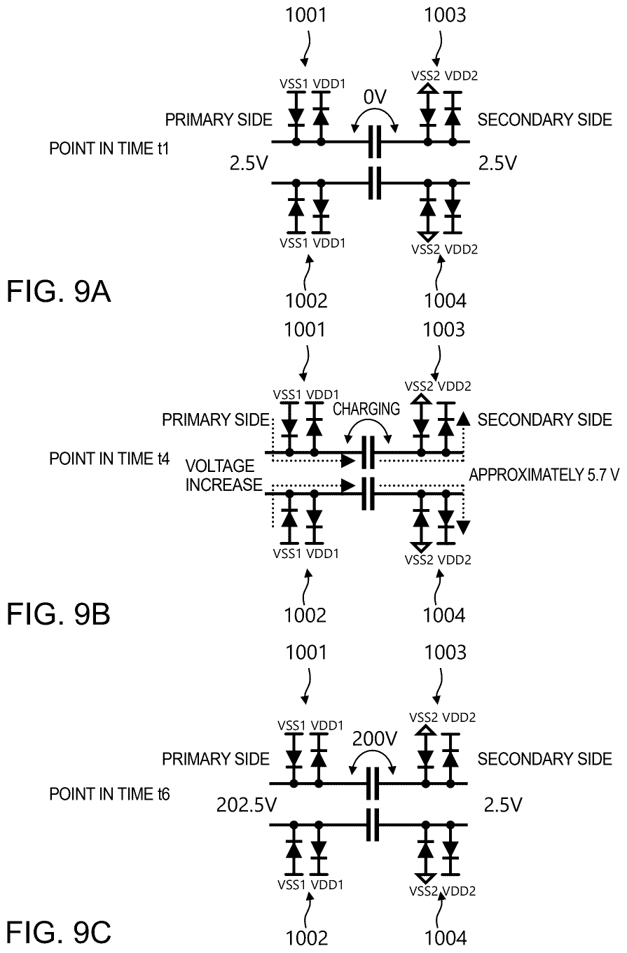

FIGS. 9A to 9C are supplementary explanatory diagrams of FIG. 8 and illustrate detailed configurations of the protection circuits 1001 to 1004, operation states of the protection circuits 1001 to 1004 at points in time t1, t4, and t6 in FIG. 8 and the common mode voltages on the primary side and the secondary side of the capacitor.

In FIG. 8, in a state at the point in time t1, the common mode voltages on the primary side and the secondary side are in the same state. For example, both VSS1 and VSS2 are 0 V, and VDD1 and VDD2 are both 5 V. Therefore, both the common mode voltages on the primary side and the secondary side are 2.5 V. A state between the two terminals of the capacitors of the electromagnetic field coupler 1 becomes a state in which 0 V is held between the two terminals (see FIG. 9A).

From a point in time t2 to a point in time t5, the common mode voltage on the primary side increases. For example, VSS1 fluctuates to be 200 V, and VDD1 fluctuates to be 205 V, so that the common mode voltage becomes 202.5 V. That is, the common mode voltage increases by 200 V.

From the point in time t2, VSS1 and VDD1 start to increase, but since the voltage between the terminals of the capacitors in the electromagnetic field coupler 1 acts to maintain 0 V, the common mode voltage on the primary side is put into a state in which approximately 2.5 V is held until t3.

At the point in time t3, VSS1 exceeds operation thresholds of the protection circuits 1001 and 1002 on the primary side, and electric charges start to be supplied to the terminals on the primary side of the capacitors of the electromagnetic field coupler 1 from VSS1 (see FIG. 9B). The potentials at the terminals on the primary side of the capacitors start to increase. However, in general, an input impedance on the secondary side is high, and the voltage between the terminals of the capacitors acts to maintain 0 V. Therefore, the potentials at the terminals on the secondary side of the capacitors start to increase at the same time. When the potentials further increase, a voltage on a signal line P2′ and a signal line N2′ exceeds operation thresholds of the protection circuits 1003 and 1004 on the secondary side, and electric charges start to be discharged from the terminals on the secondary side of the capacitors to VDD2 (see FIG. 9B). Charging is performed in a manner that electric charges are supplied to the capacitors of the electromagnetic field coupler 1 from VSS1 on the primary side, and electric charges are extracted to VDD2 on the secondary side (see FIG. 9B).

The increase in the common mode voltage on the primary side stops at the point in time t5, but a timing at which charging and discharging of the capacitors of the electromagnetic field coupler 1 end and the state returns to a steady state is the point in time t6 (see FIG. 9C). During a period from the point in time t3 to the point in time t6 in which the common mode voltage on the secondary side increases and returns to its original state, a voltage that exceeds an input range is input to the demodulator 50 on the secondary side. For this reason, a normal output signal is not obtained from the demodulator 50, and a CMTI characteristic and a CMRR characteristic are substantially degraded.

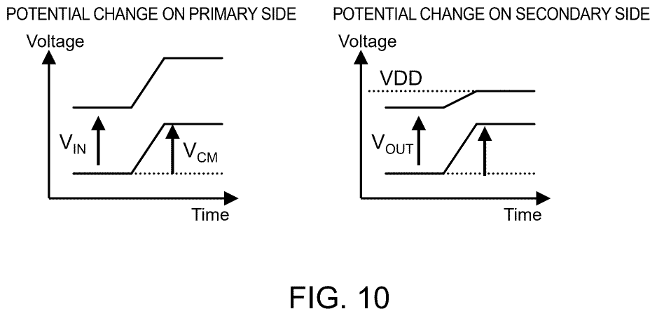

FIG. 10 is a diagram for describing that due to the fluctuation of the common mode voltage on the primary side, the potential on the secondary side fluctuates, and a normal output signal is obtained. When a common mode voltage V_{CM} of an input signal V_{IN} rapidly rises on the primary side, it becomes unable to track the fluctuation of this potential due to an upper limit of VDD on the secondary side. For this reason, an output voltage Vₒᵤₜ is distorted, and it is understood that a normal output is not obtained.

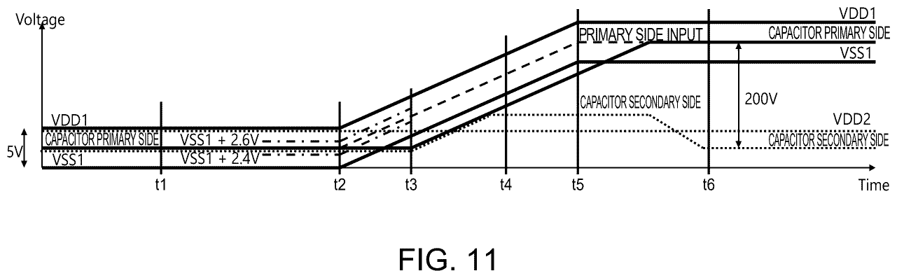

It is noted that in FIG. 8, for simplicity, a state in which there is no input signal (state in which signal transmission is not performed) is considered, but FIG. 11 illustrates a graphic representation obtained by adding a graph of an input signal in a case where the input signal exists (graph of a “primary side input”) to FIG. 8. FIG. 11 is the same as FIG. 8 except for that the graph of the input signal is added.

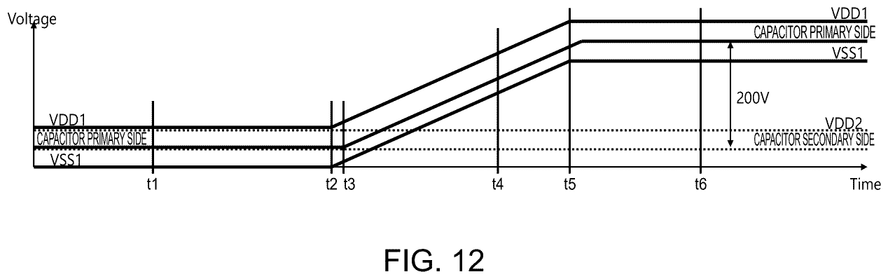

FIG. 12 illustrates an operation example in a case where the common mode voltage on the primary side steeply rises in the configuration example of FIG. 1.

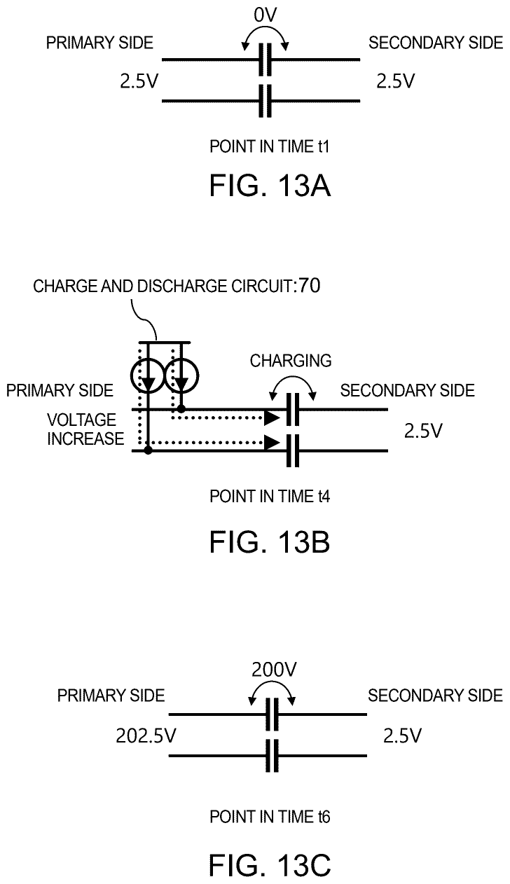

FIGS. 13A to 13C are supplementary explanatory diagrams of FIG. 12 and illustrate operation states of the charge and discharge circuit at the points in time t1, t4, and t6 in FIG. 12 and common mode voltages on the primary side and the secondary side of operative capacitors.

A state at the point in time t1 (see FIG. 13A) is similar to that of FIG. 8, and the common mode voltage on the primary side increases from the point in time t2 to the point in time t5.

VSS1 and VDD1 start to increase from the point in time t2, but since the voltage between the terminals of the capacitors in the electromagnetic field coupler 1 acts to maintain 0 V, the potential (common mode voltage) on the primary side is put into a state in which approximately 2.5 V is held until the point in time t3.

At the point in time t3, the potential fluctuation detector 60 detects a fluctuation (increase) of the common mode voltage, and the charge circuit 71 of the charge and discharge circuit 70 starts to be driven. Electric charges are charged to the terminals on the primary side of the capacitors (capacitances) by the charge circuit 71 of the charge and discharge circuit 70. FIG. 13B illustrates a state in which electric charges are charged to the terminals on the primary side. Since electric charges are intentionally charged from the primary side, during this period, the potentials at the terminals on the secondary side of the capacitors hardly fluctuate. In other words, the amount of electric charges sufficient for the fluctuation of the common mode voltage can be supplied from the terminals on the primary side of the capacitors by the charge and discharge circuit 70, so that it is possible to suppress the potential fluctuation on the terminal side on the secondary side as a result of receiving this influence.

At the point in time t5, when the increase of VSS1 and the increase of VDD1 stop, the detection of the fluctuation of the common mode voltage by the potential fluctuation detector 60 also stops after a short delay, and the charge operation by the charge circuit 71 of the charge and discharge circuit 70 also stops.

As compared with the operation in the comparative example illustrated in FIG. 8, during a period from the point in time t3 to the point in time t6, the potential fluctuations on the secondary side of the capacitors of the electromagnetic field coupler 1 can be suppressed. With this configuration, the CMTI characteristic and the CMRR characteristic can be improved.

### Case Where Common Mode Voltage on Primary Side Steeply Falls

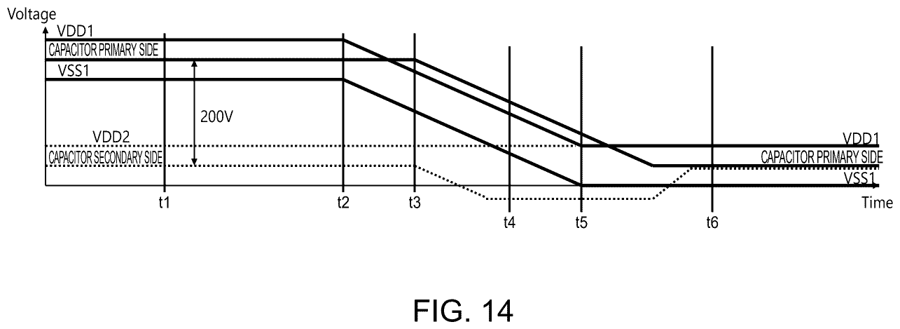

FIG. 14 illustrates an operation example in a case where the common mode voltage on the primary side steeply falls in the configuration of the comparative example illustrated in FIG. 7. Herein, for simplicity, a state in which signal transmission is not performed is assumed.

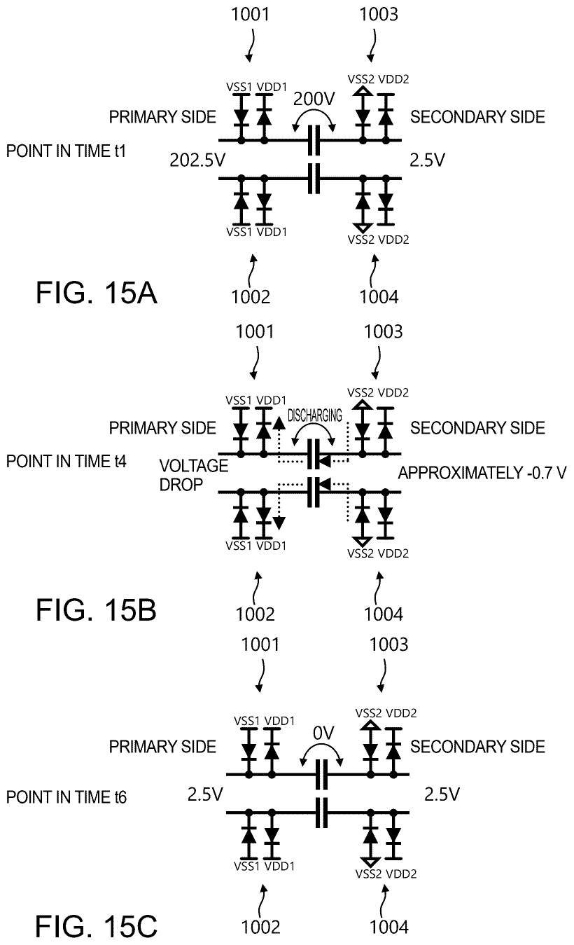

FIGS. 15A to 15C are supplementary explanatory diagrams of FIG. 14 and illustrate detailed configurations of the protection circuits 1001 to 1004, the operation states of the protection circuits 1001 to 1004 at the points in time t1, t4, and t6 in FIG. 14, and the common mode voltages on the primary side and the secondary side of the capacitors.

As may be understood from FIG. 14, the operation is similar to the above-described rise case except that a current path is reversed. It is noted that at the point in time t4, since the secondary side of the capacitors is charged from VSS2, the common mode voltage on the secondary side significantly falls.

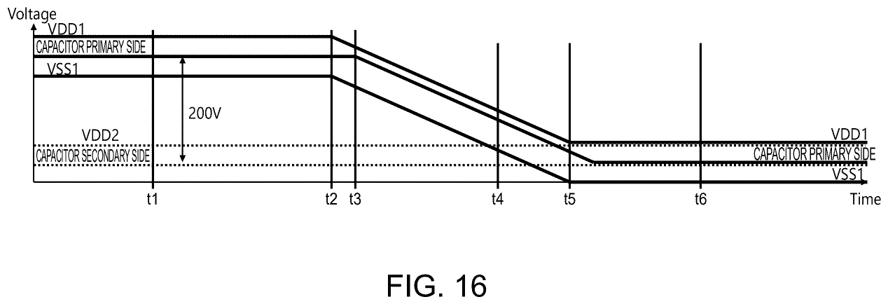

FIG. 16 illustrates an operation example in a case where the common mode voltage on the primary side steeply falls in the configuration example of FIG. 1. Herein, for simplicity, a state in which signal transmission is not performed is assumed.

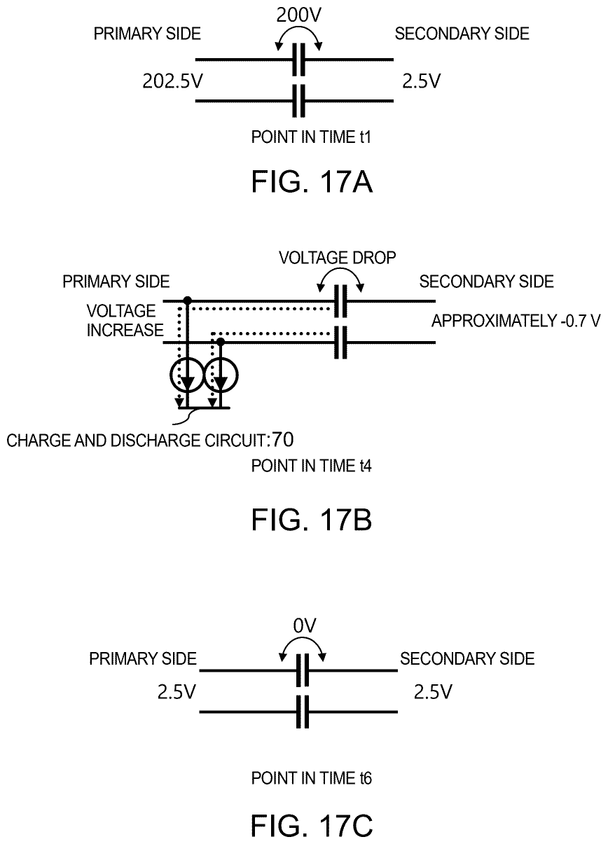

FIGS. 17A to 17C are supplementary explanatory diagrams of FIG. 16 and illustrate the operation state of the charge and discharge circuit at the points in time t1, t4, and t6 in FIG. 16 and the common mode voltages on the primary side and the secondary side of the operative capacitors.

The potential fluctuation detector 60 detects a common mode fluctuation at the point in time t3, and the discharge circuit 72 of the charge and discharge circuit 70 intentionally extracts electric charges from the terminals on the primary side of the capacitors (see FIG. 17B). With this configuration, the potential fluctuations on the secondary side of the capacitors of the electromagnetic field coupler 1 can be suppressed. In other words, the amount of electric charges sufficient for the fluctuation of the common mode voltage can be extracted by the discharge circuit 72 of the charge and discharge circuit 70 from the primary side of the capacitors, so that it is possible to suppress the potential fluctuation on the secondary side as a result of receiving this influence. With this configuration, the CMTI characteristic and the CMRR characteristic can be improved.

### OTHER CONFIGURATION EXAMPLE 1

In the configuration example of FIG. 1, the potential fluctuation detector and the charge and discharge circuit are provided in the primary side (high voltage side), but the potential fluctuation detector and the charge and discharge circuit may be provided in both the primary side (high voltage side) and the secondary side (low voltage side). In this case, in a case where the current amount (electric charge amount) is not sufficient by using only the charge and discharge circuit on the primary side or the like, additional currents (electric charges) can be supplied on the secondary side. By performing charging and discharging from both the primary side and the secondary side, even in a case where an even more steep common mode fluctuation occurs, improvements in the CMTI characteristic and the CMRR characteristic can be expected.

### OTHER CONFIGURATION EXAMPLE 2

The protection circuits are not provided in the configuration example of FIG. 1, but the protection circuits may be provided similarly as in the comparative example.

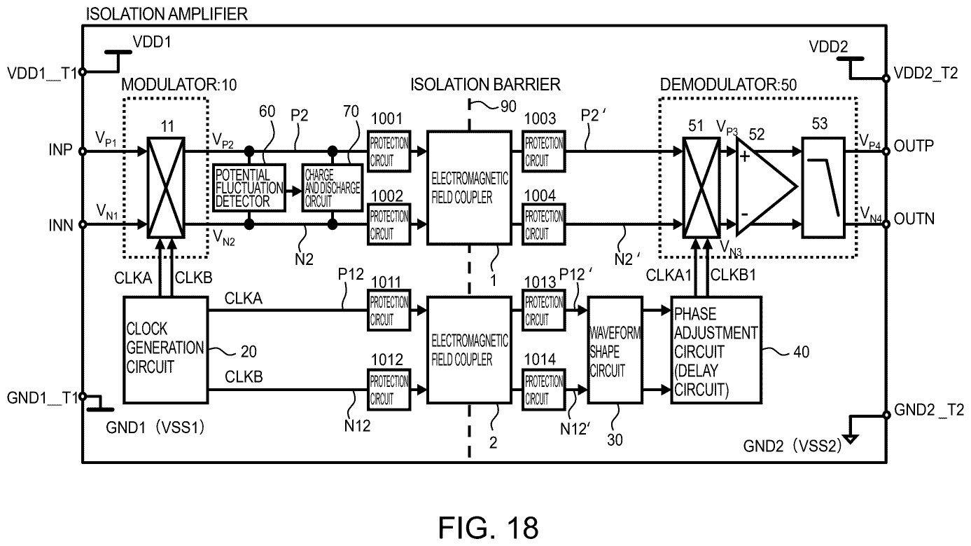

FIG. 18 illustrates an example in which protection circuits are added to the configuration of FIG. 1. By the operations of the potential fluctuation detector 60 and the charge and discharge circuit 70 of the present embodiment, the protection circuits 1001 to 1004 (first protection circuits) and the protection circuits 1011 to 1014 (second protection circuits) do not operate for the purpose of suppressing the fluctuation of the common mode voltage on the secondary side but have a function of protecting internal circuits by diverting (bypassing) the voltage to the power supply potential or the reference potential in a case where an abnormal excessive voltage is input to the internal circuits from the isolation barrier or the like. The protection circuits are, for example, clamping diodes or electrostatic discharge (ESD) protection circuits.

### SECOND EMBODIMENT

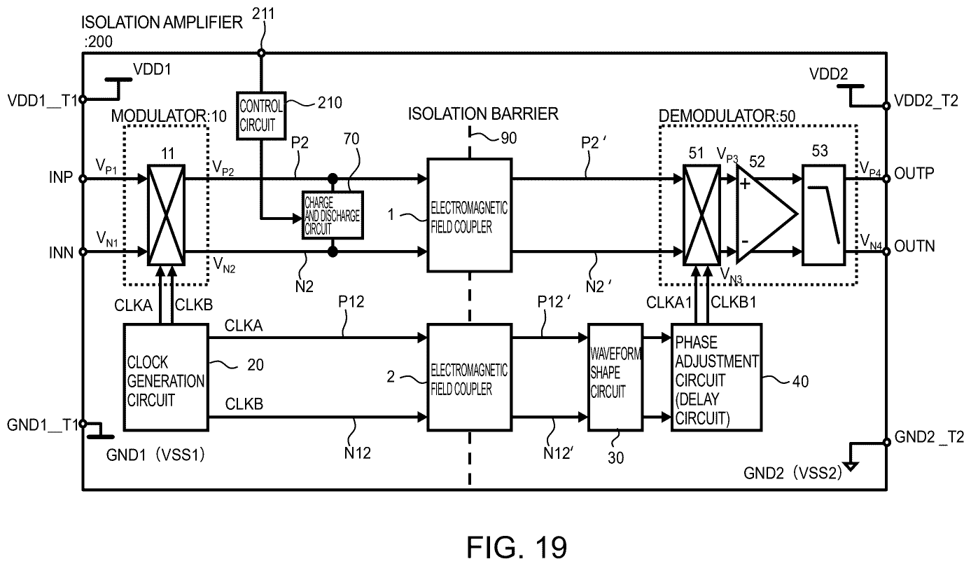

FIG. 19 illustrates an isolation amplifier 200 according to a second embodiment. The charge and discharge circuit 70 is controlled by a control circuit 210. A control signal for driving an external gate driver or a signal synchronized with the control signal is input to a control input terminal 211, for example. The control circuit 210 controls the charge and discharge circuit 70 based on the signal input to the control input terminal 211.

In the first embodiment, the charge and discharge circuit 70 is driven when the potential fluctuation detector 60 detects the fluctuation of the common mode voltage on the primary side, but in the present embodiment, the control circuit 210 controls the charge and discharge circuit 70 based on the control signal for driving the gate driver. The fluctuation of the common mode voltage on the primary side is caused when a switch element driven by the gate driver operates. In other words, a fluctuation timing of the common mode voltage on the primary side is known, and when the control circuit 210 drives the charge and discharge circuit 70 in synchronization with the control signal for driving the gate driver, the potential fluctuations on the secondary side of the capacitors of the electromagnetic field coupler 1 can be suppressed. With this configuration, the CMTI characteristic and the CMRR characteristic can be improved.

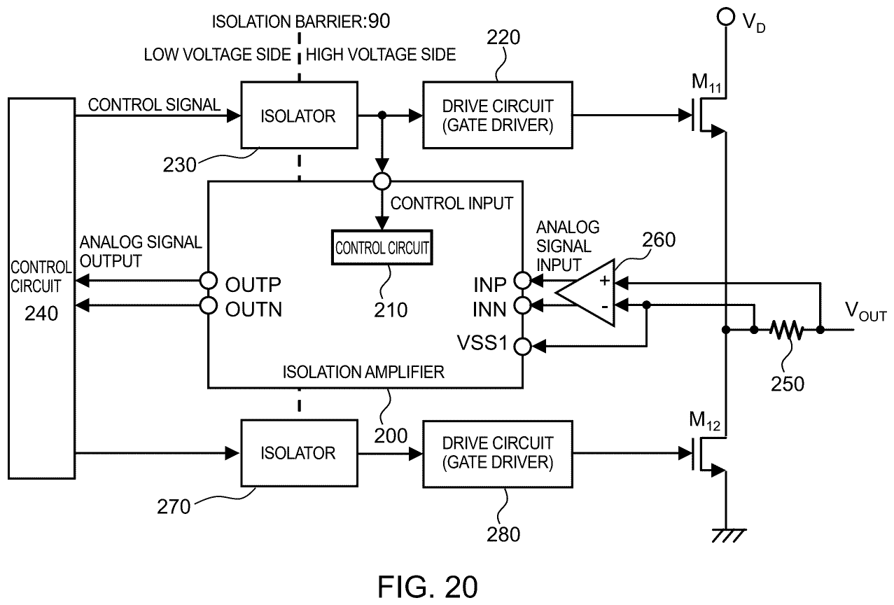

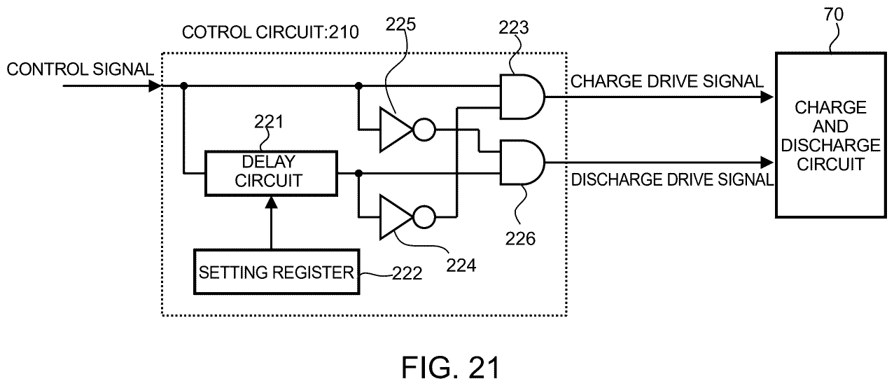

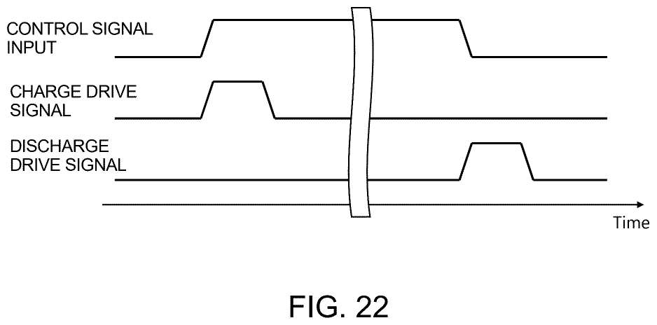

FIG. 20 illustrates a connection example between the isolation amplifier 200 and peripheral circuits including gate drivers. FIG. 21 illustrates a configuration example of the control circuit 210. FIG. 22 is a timing chart illustrating an operation example of the control circuit 210.

When an analog signal on a high side of a half bridge including switch elements M₁₁ and M₁₂ that are connected in series is transmitted to a low voltage side, to suppress the fluctuation of the common mode voltage on the secondary side, the control circuit 210 of the isolation amplifier 200 is used. More specifically, a current on an output side of the half bridge is detected by a shunt resistor 250 as a voltage signal, and a signal obtained by amplifying this voltage signal by an amplifier 260 is set as an input analog signal of the isolation amplifier 200. When this analog signal is transmitted to the low voltage side, the fluctuation of the common mode voltage on the secondary side is suppressed by using the control circuit 210 of the isolation amplifier 200. It is noted that the left side is the high voltage side, and the right side is the low voltage side in FIG. 1, but the right side is the high voltage side, and the left side is the low voltage side in FIG. 20.

A control signal for driving the gate driver 220 is input from an isolator 230 to a gate driver (drive circuit) 220 on the high side. The control signal is, for example, a PWM signal (see a graph of the control signal input in FIG. 22) and is generated by a control circuit 240. This control signal is also input to the control circuit 210 of the isolation amplifier 200. It is noted that a control signal for driving a gate driver 280 which is generated by the control circuit 240 is input to the gate driver 280 via an isolator 270 on a low side too.

The control circuit 210 in the isolation amplifier 200 generates a charge drive signal and a discharge drive signal as signals for controlling the charge and discharge circuit 70 based on this control signal. More specifically, this control signal is input to an AND circuit 223 as illustrated in FIG. 21 and is also input to a delay circuit 221. The signal input to the delay circuit 221 is delayed by a time period set by a setting register 222 and inverted by an inverter 224 and is thereafter input to the AND circuit 223. As a result, a pulse signal which is set to High level for a time period equivalent to a delay amount of the delay circuit 221 (first time period) from a rising edge of the control signal is output from the AND circuit 223 as the charge drive signal (see a graph of the charge drive signal in FIG. 22). When the control signal rises, the switch element M₁₁ is turned ON by the gate driver 220, and the common mode voltage on the primary side increases. At this time, the charge drive signal is set to High level (pulse is output), so that the charge and discharge circuit 70 starts the charge operation. With this configuration, the abrupt fluctuation of the common mode voltage on the secondary side is suppressed.

In addition, the control signal input to the control circuit 210 is inverted by an inverter 225 and is thereafter input to an AND circuit 226, and the control signal delayed by the delay circuit 221 is also input to the AND circuit 226. As a result, a pulse signal which is set to High level for a time period equivalent to a delay amount of the delay circuit 221 (second time period) from a falling edge of the control signal is output from the AND circuit 226 as the discharge drive signal (see a graph of the discharge drive signal in FIG. 22). When the control signal falls, the switch element M₁₁ is turned OFF by the gate driver 220, and the common mode voltage drops. At this time, the discharge drive signal turns to High level (pulse is output), so that the charge and discharge circuit 70 starts the discharge operation. With this configuration, the abrupt fluctuation of the common mode voltage on the secondary side is suppressed.

In the configuration example of FIG. 21, a pulse width of the charge drive signal when the switch element M₁₁ is ON and a pulse width of the discharge drive signal when the switch element M₁₁ is OFF are the same, but the control circuit 210 may be configured such that those pulse widths are set to be different from each other. Each of the charge drive signal and the discharge drive signal is a single bit signal but may be set as an output of multiple bits depending on a setting value in the setting register 222, and a drive current amount (a charge amount and a discharge amount) of the charge and discharge circuit 70 may be adjustable.

### THIRD EMBODIMENT

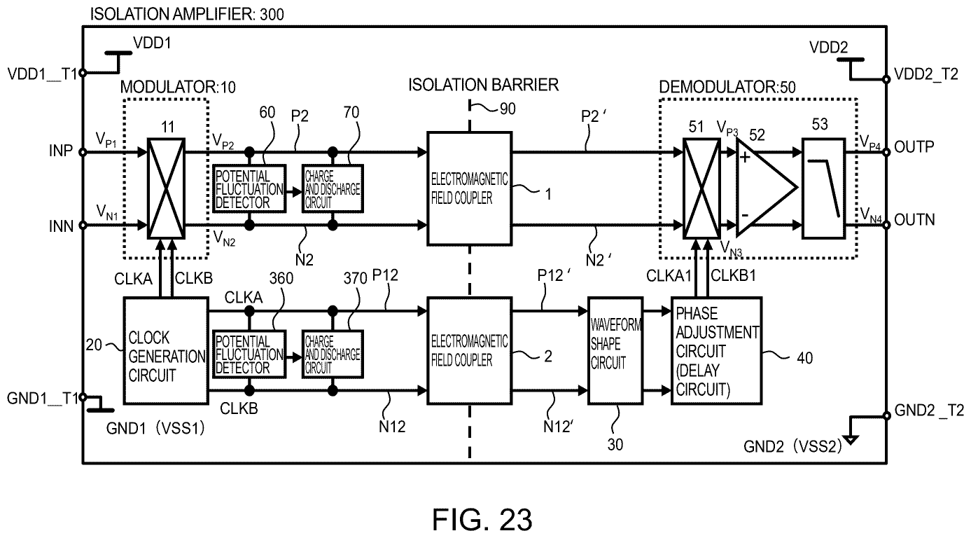

FIG. 23 illustrates an isolation amplifier 300 according to a third embodiment. A difference from the first embodiment resides in that a potential fluctuation detector 360 (second detection circuit) and a charge and discharge circuit 370 (second charge and discharge circuit) are provided in the transmission paths (the signal lines P12 and N12) of the clock signals on the primary side as well. Operations of the potential fluctuation detector 360 and the charge and discharge circuit 370 are similar to those of the potential fluctuation detector 60 and the charge and discharge circuit 70 in the transmission paths (the signal lines P2 and N2) of the analog signals. In addition, a graph of the common mode voltage (clock average voltage) at the time of clock signal transmission is similar to the graph of the common mode voltage (FIG. 12, FIG. 16, and the like) of the first embodiment at the time of analog signal transmission.

With the provision of the potential fluctuation detector 360 and the charge and discharge circuit 370, the potential fluctuations of the reception signals on the secondary side (fluctuation of the common mode voltage) caused by the fluctuation of the common mode voltage of the clock signals on the primary side can be suppressed. With this configuration, the CMTI characteristic and the CMRR characteristic can be improved, and also missing of clock signals transmitted to the secondary side can be avoided. Thus, a temporary fluctuation of the analog signal output which is caused by the fluctuation of the common mode voltage can be reduced.

### FOURTH EMBODIMENT

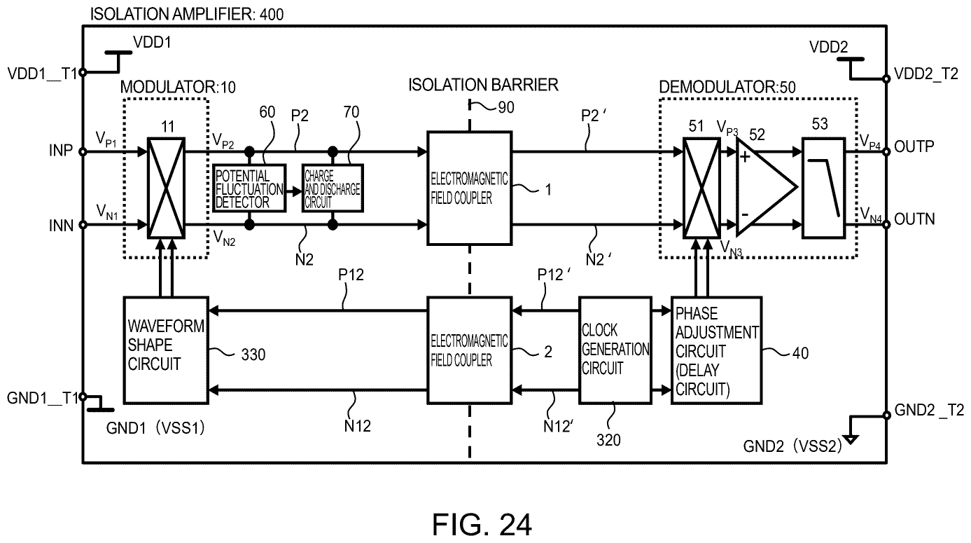

FIG. 24 illustrates an isolation amplifier 400 according to a fourth embodiment. Clock signals used for the modulation of the analog signals on the primary side and the demodulation of the analog signals transmitted to the secondary side are generated by a clock generation circuit 320 on the secondary side. The clock generation circuit 320 generates the clock signals to be transmitted to a waveform shape circuit 330 via the electromagnetic field coupler 2. In addition, the clock generation circuit 320 transmits the generated clock signals to the phase adjustment circuit 40.

The waveform shape circuit 330 adjusts amplitudes of the clock signals transmitted via the electromagnetic field coupler 2 to be supplied to the modulator 10. The phase adjustment circuit 40 adjusts phases of the clock signals to be supplied to the demodulator 50.

In the configuration in which the clock signals are transmitted from the secondary side to the primary side in the above-described manner too, the potential fluctuation detector 60 and the charge and discharge circuit 70 which are provided in the transmission paths of the analog signals on the primary side operate similarly as in the first embodiment. With this configuration, the fluctuations of the potentials of the reception signals on the secondary side caused by the fluctuation of the common mode voltage on the primary side can be suppressed. Thus, the CMTI characteristic and the CMRR characteristic can be improved.

### FIFTH EMBODIMENT

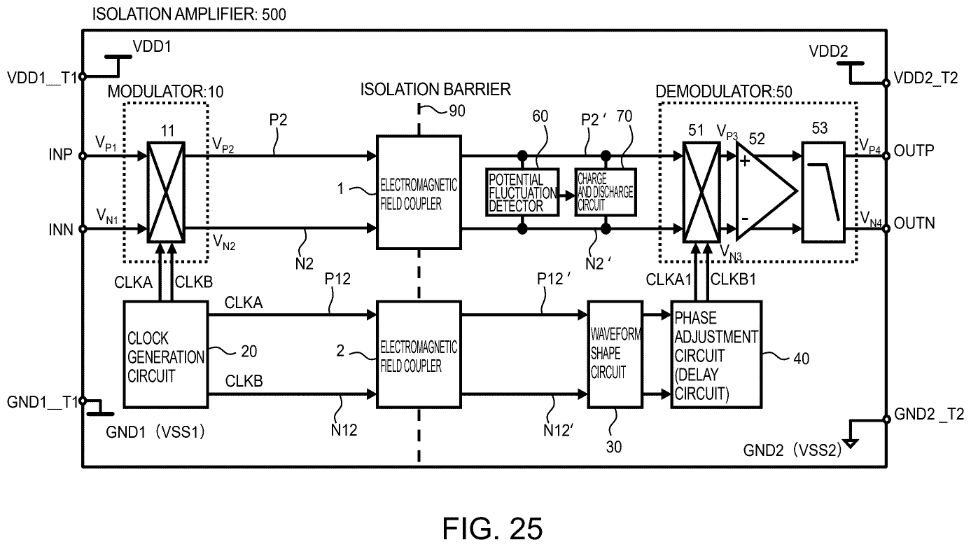

FIG. 25 illustrates an isolation amplifier 500 according to a fifth embodiment. The potential fluctuation detector 60 and the charge and discharge circuit 70 are provided in the transmission paths (signal lines P2′ and N2′) of the analog signals on the secondary side. The signal lines P2′ and N2′ correspond to the second signal lines through which the second signals are transmitted.

When the potential fluctuation detector 60 detects the fluctuation of the common mode voltage on the secondary side to drive the charge and discharge circuit 70, the voltage is controlled in a manner that the voltage does not exceed an input range of the demodulator 50. With this configuration, similarly as in the first embodiment, the fluctuation of the common mode voltage on the secondary side can be suppressed. Thus, the CMTI characteristic and the CMRR characteristic can be improved.

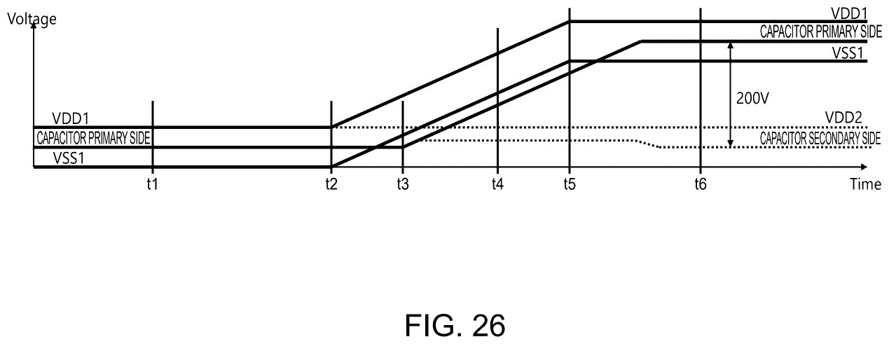

FIG. 26 illustrates an operation example in a case where the common mode voltage on the primary side steeply rises in a configuration example of FIG. 25. Herein, for simplicity, a state in which signal transmission is not performed is assumed.

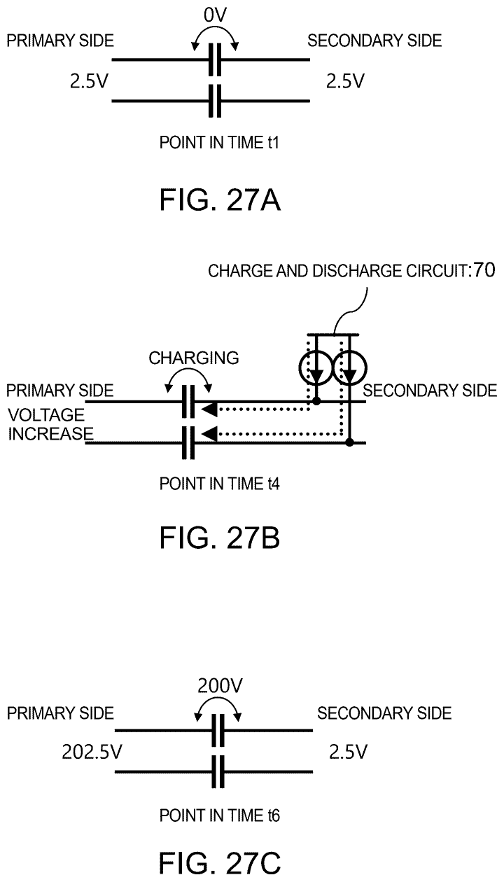

FIGS. 27A to 27C are supplementary explanatory diagrams of FIG. 26 and illustrate the operation state of the charge and discharge circuit at the points in time t1, t4, and t6 and the common mode voltages on the primary side and the secondary side of the operative capacitors.

A state at the point in time t1 (see FIG. 27A) is similar to that of FIG. 12 in the first embodiment, and the common mode voltage on the primary side increases from the point in time t2 to the point in time t5.

VSS1 and VDD1 start to increase from the point in time t2, but since the voltage between the terminals of the capacitors in the electromagnetic field coupler 1 acts to maintain 0 V, the potential (common mode voltage) on the primary side is put into a state in which approximately 2.5 V is held until the point in time t3.

The potential fluctuation detector 60 on the secondary side detects the fluctuation of the common mode voltage at the point in time t3 after a delay from the point in time t2 (after a delay as compared with a case where detection is performed on the primary side in the first embodiment). That is, a timing at which the fluctuation is detected is delayed on the secondary side as compared with a case of the primary side. The charge and discharge circuit 70 operates, and electric charges start to be charged to the terminals on the secondary side of the capacitors (see FIG. 27B). Since the common mode voltage on the secondary side slightly increases from the point in time t3 until the start of the charge operation of the charge and discharge circuit 70, although the potential fluctuation on the secondary side cannot be canceled as much as in the first embodiment, the increase in the potential can be suppressed after the start of the charge operation of the charge circuit 71. For this reason, as compared with the above-described comparative example, an improvement effect of CMTI can be expected.

At the point in time t5, when the increase of VSS1 and the increase of VDD1 stop, the detection of the fluctuation of the common mode voltage by the potential fluctuation detector 60 also stops after a delay, and the charge and discharge circuit 70 also stops (see FIG. 27C).

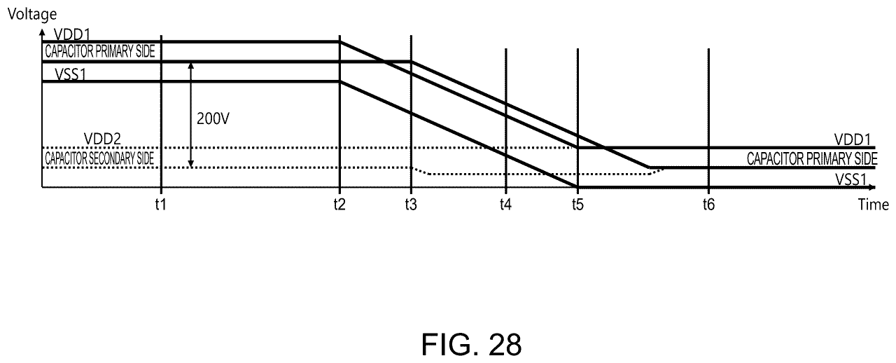

FIG. 28 illustrates an operation example in a case where the common mode voltage on the primary side steeply falls in the configuration example of FIG. 25. Herein, for simplicity, a state in which signal transmission is not performed is assumed.

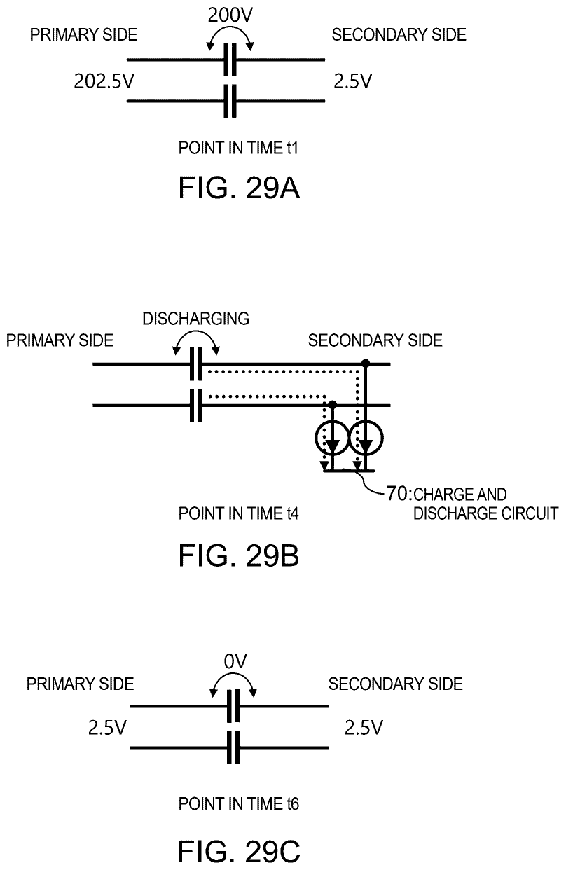

FIGS. 29A to 29C are supplementary explanatory diagrams of FIG. 28 and illustrate the operation state of the charge and discharge circuit at the points in time t1, t4, and t6 and the common mode voltage on the primary side and the secondary side of the operative capacitors.

A fall of the common mode voltage on the primary side starts from the point in time t2, and the potential fluctuation detector 60 on the secondary side detects the fluctuation of the common mode voltage at the point in time t3 after a delay from the point in time t2 (after a delay as compared with a case where the detection is performed on the primary side in the first embodiment). That is, the timing at which the fluctuation is detected is delayed on the secondary side as compared with a case of the primary side. The charge and discharge circuit 70 operates, and electric charges are intentionally extracted from the terminals on the secondary side of the capacitors (see FIG. 29B). With this configuration, the potential fluctuations on the secondary side of the capacitors of the electromagnetic field coupler 1 can be suppressed. In other words, the amount of electric charges sufficient for the fluctuation of the common mode voltage from the secondary side of the capacitors is extracted by the charge and discharge circuit 70, so that the potential fluctuation on the secondary side can be suppressed. With this configuration, the CMTI characteristic and the CMRR characteristic can be improved.

### SIXTH EMBODIMENT

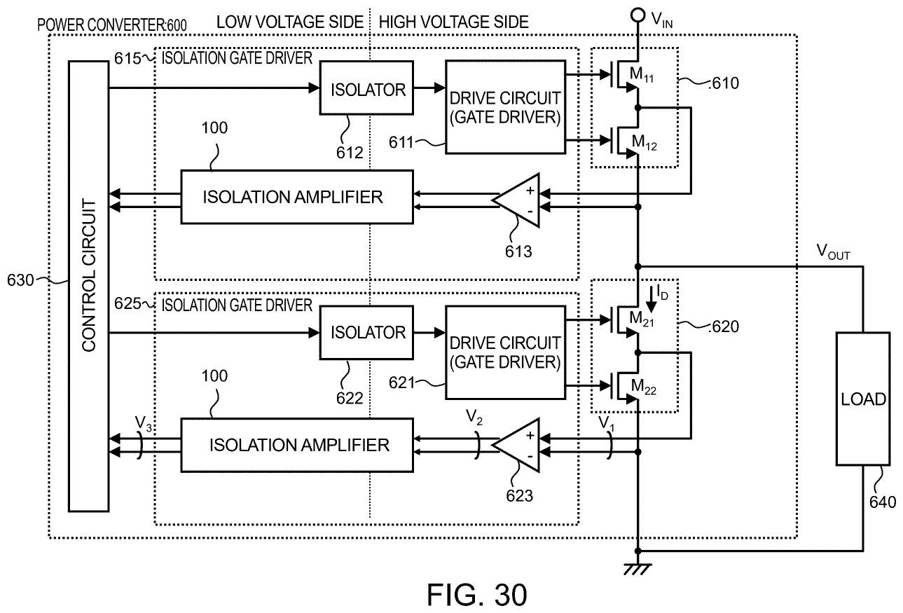

FIG. 30 illustrates a configuration example of a power converter 600 according to a sixth embodiment.

A switch element device 610 on the high side in which the switch element M₁₁ and a current detection element M₁₂ are connected in series, and a switch element device 620 on the low side in which a switch element M₂₁ and a current detection element M₂₂ are connected in series are provided in the high voltage side. The switch elements M₁₁ and M₂₁ and the current detection elements M₁₂ and M₂₂ are, for example, GaN elements, LVMOS elements, or SiC elements. These switch element devices 610 and 620 are connected in series to form the half bridge, and a load apparatus 640 is connected in parallel with the switch element device 620. The power converter 600 supplies the voltage Vₒᵤₜ to the load apparatus 640 by controlling the switch element M₁₁ and the current detection element M₁₂ of the switch element device 610 and the switch element M₂₁ and the current detection element M₂₂ of the switch element device 620. The switch element M₂₁ and the current detection element M₂₂ in the switch element device 620 respectively correspond to a first switch element and a second switch element.

An isolation gate driver 615 is provided so as to correspond to the switch element device 610, and an isolation gate driver 625 is provided so as to correspond to the switch element device 620. In addition, a control circuit 630 configured to control the switch element devices 610 and 620 via these isolation gate drivers 615 and 625 is provided.

The isolation gate driver 615 includes an amplifier 613, the isolation amplifier 100, an isolator 612, and a drive circuit 611. The isolation gate driver 625 includes an amplifier 623, the isolation amplifier 100, an isolator 622, and a drive circuit 621. Herein, the isolation amplifier 100 (see FIG. 1) according to the first embodiment is used in each of the isolation gate drivers, but the isolation amplifiers 200 to 500 according to any of the second embodiment to the fifth embodiment may be used.

The amplifier 623 of the isolation gate driver 625 detects a voltage V₁ between terminals (a drain terminal and a source terminal) of the current detection element M₂₂. That is, in the current detection element M₂₂, the voltage V₁ is generated between the terminals of the element by a current I_{D} flowing through its on-resistance R_{ON}. The voltage V₁ is calculated by the following expression (1) based on the on-resistance (denoted as R_{ON}) of the current detection element M₂₂ and the current I_{D} flowing through the current detection element M₂₂.

V₁=R_{ON}×I_{D} (1)

The amplifier 623 amplifies the detected voltage V₁ by an amplification factor “A” and inputs differential analog signals (voltage signal) indicating a voltage V₂ after the amplification to the isolation amplifier 100. The voltage V₂ is represented by the following expression (2) based on the on-resistance R_{ON}, the current I_{D}, and the amplification factor “A”.

V₂=A×V₁=A×R_{ON}×I_{D} (2)

The isolation amplifier 100 transmits the analog signals indicating the voltage V₂ from the high voltage side (primary side) to the low voltage side (secondary side), and outputs the transmitted analog signals to the control circuit 630. When the amplification factor of the isolation amplifier 100 is set as 1 (0 dB), a voltage V₃ indicated by the transmitted analog signals is represented by the following expression (3).

V₃=V₂=A×R_{ON}×I_{D} (3)

The control circuit 630 generates control signals to instruct timings to turn ON and turn OFF the switch element M₂₁ and the current detection element M₂₂ based on the voltage V₃ indicated by the signals input from the isolation amplifier 100. More specifically, the control circuit 630 calculates a value of the current I_{D} from the amplification factor “A” of the amplifier 623, the on-resistance R_{ON} of the current detection element M₂₂, and the voltage V₃ based on the expression (3), and generates the control signal according to the calculated value of the current I_{D}. In a case where the amplification factor “A” of the amplifier 623 and the on-resistance R_{ON} of the switch element are known, the control circuit 630 can calculate the current I_{D} from the voltage V₃.

The control circuit 630 transmits the generated control signal to the drive circuit 621 via the isolator 622. The isolator 622 is an isolation element that isolates the primary side and the secondary side. A capacitor or a transformer can be used as the isolation element. Alternatively, a photo coupler or a digital isolator may be used. The drive circuit 621 generates a gate drive signal based on the control signal received via the isolator 622, and supplies the gate drive signal to the switch element M₂₁ and the current detection element M₂₂. In this manner, the current I_{D} is controlled.

The current I_{D} is highly accurately detected at a high speed in this manner, and also feedback control based on the detected current I_{D} is performed, so that a switch loss of the switch element can be reduced, and a conversion efficiency of the power converter can be improved.

The operation of the isolation gate driver 625 has been described, but the operation of the isolation gate driver 615 is similar to that of the isolation gate driver 625 except that the drive target is the switch element device 610 on the high side.

As described above, according to the present embodiment, the current I_{D} of the switch element can be detected, and the signal according to the detected current I_{D} can be fed back to the low voltage side at a high SN ratio. With this configuration, the switch element can be highly accurately controlled. As a result, the switch loss of the switch element can be reduced, and the conversion efficiency of the power converter as a whole can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

The embodiments as described before may be configured as below.

### (Clauses)

Clause 1. An electronic circuitry comprising:
a first conversion circuit configured to convert an input signal into a first signal having a frequency according to a first clock signal, the input signal being a differential signal;
a first electromagnetic field coupler having a first terminal and a second terminal, and configured to transmit the first signal received at the first terminal to the second terminal as a second signal via a first isolation element including a capacitance;
a second conversion circuit configured to convert the second signal into an output signal having a frequency according to the input signal based on the first clock signal; and
a first charge and discharge circuit configured to charge or discharge the capacitance of the first electromagnetic field coupler from at least one of the first terminal and the second terminal in response to a voltage of a direct current component of the first signal fluctuating, to suppress a fluctuation of a voltage of a direct current component of the second signal.

Clause 2. The electronic circuitry according to clause 1, further comprising: a first detection circuit configured to measure the first signal or the second signal to detect the voltage of the direct current component of the first signal or the second signal, wherein the first charge and discharge circuit charges or discharges the capacitance of the first electromagnetic field coupler based on the voltage of the direct current component detected by the first detection circuit.

Clause 3. The electronic circuitry according to clause 2, wherein the first charge and discharge circuit
performs charging when the voltage of the direct current component detected by the first detection circuit is less than a first reference voltage,
performs discharging when the voltage of the direct current component is greater than a second reference voltage, and
performs neither charging nor discharging when the voltage of the direct current component is greater than or equal to the first reference voltage and less than or equal to the second reference voltage.

### Clause 4. the Electronic Circuitry According to Clause 3, Wherein the First detection circuit includes:

a first comparator configured to compare the voltage of the direct current component detected by the first detection circuit with the first reference voltage to generate a first comparison result signal; and
a second comparator configured to compare the voltage of the direct current component detected by the first detection circuit with the second reference voltage to generate a second comparison result signal,
wherein the first charge and discharge circuit performs the charging or the discharging based on the first comparison result signal and the second comparison result signal.

Clause 5. The electronic circuitry according to clause 3, wherein the first reference voltage is a sum of a reference potential of the first signal or the second signal and a first predetermined value, and
the second reference voltage is a sum of the reference potential and a second predetermined value larger than the first predetermined value.

Clause 6. The electronic circuitry according to clause 1, wherein the input signal is a voltage signal across both terminals of a switch element controlled according to a control signal, and
the first charge and discharge circuit performs the charging or the discharging based on the control signal.

Clause 7. The electronic circuitry according to clause 6, wherein the first charge and discharge circuit performs the charging for a first time period in response to a timing at which the control signal indicates turn-on of the switch element, and performs the discharging for a second time period in response to a timing at which the control signal indicates turn-off of the switch element.

Clause 8. The electronic circuitry according to clause 1, further comprising: a clock generation circuit configured to generate the first clock signal, wherein the first conversion circuit converts the input signal into the first signal based on the first clock signal generated by the clock generation circuit,
the electronic circuitry further comprising: a second electromagnetic field coupler having a third terminal and a fourth terminal, and configured to transmit the first clock signal received at the third terminal to the fourth terminal as a second clock signal via a second isolation element including a capacitance;
the second conversion circuit converts the second signal into the output signal based on the second clock signal; and
the electronic circuitry further comprising: a second charge and discharge circuit configured to charge or discharge the capacitance of the second electromagnetic field coupler from at least one of the third terminal and the fourth terminal in response to a voltage of a direct current component of the first clock signal fluctuating, to suppress a fluctuation of a voltage of a direct current component of the second clock signal.

Clause 9. The electronic circuitry according to clause 8, further comprising: a second detection circuit configured to measure the first clock signal or the second clock signal to detect the voltage of the direct current component of the first clock signal or the second clock signal,
wherein the second charge and discharge circuit charges or discharges the capacitance of the second electromagnetic field coupler based on the voltage of the direct current component detected by the second detection circuit.

### Clause 10. the Electronic Circuitry According to Clause 9, Wherein the Second

charge and discharge circuit performs charging when the voltage of the direct current component detected by the second detection circuit is less than a first reference voltage,
performs discharging when the voltage of the direct current component is greater than a second reference voltage, and
performs neither charging nor discharging when the voltage of the direct current component is greater than or equal to the first reference voltage and less than or equal to the second reference voltage.

### Clause 11. the Electronic Circuitry According to Clause 10, Wherein the Second detection circuit includes:

a first comparator configured to compare the voltage of the direct current component detected by the second detection circuit with the first reference voltage to generate a first comparison result signal; and
a second comparator configured to compare the voltage of the direct current component detected by the second detection circuit with the second reference voltage to generate a second comparison result signal,
wherein the second charge and discharge circuit performs the charging or the discharging based on the first comparison result signal and the second comparison result signal.

Clause 12. The electronic circuitry according to clause 10, wherein the first reference voltage is a sum of a reference potential of the first clock signal or the second clock signal and a first predetermined value, and
the second reference voltage is a sum of the reference potential and a second predetermined value larger than the first predetermined value.

Clause 13. The electronic circuitry according to clause 8, wherein the input signal is a voltage signal across both terminals of a switch element controlled according to a control signal, and the second charge and discharge circuit performs the charging or the discharging based on the control signal.

Clause 14. The electronic circuitry according to clause 13, wherein the second charge and discharge circuit performs the charging for a first time period in response to a timing at which the control signal indicates turn-on of the switch element, and performs the discharging for a second time period in response to a timing at which the control signal indicates turn-off of the switch element.

### Clause 15. the Electronic Circuitry According to Clause 1, Further Comprising:

a first protection circuit connected to the first terminal of the first electromagnetic field coupler and configured to bypass an overvoltage from outside to a power supply potential or a reference potential; and
a second protection circuit connected to the second terminal of the first electromagnetic field coupler and configured to bypass an overvoltage from outside to a power supply potential or a reference potential.

Clause 16. The electronic circuitry according to clause 1, wherein the first charge and discharge circuit includes:
one or more switches or one or more current sources, connected between a power supply potential and a first signal line transmitting the first signal or a second signal line transmitting the second signal; and
one or more switches or one or more current sources, connected between a reference potential and the first signal line or the second signal line.

Clause 17. A power converter for supplying electric power to a load apparatus, comprising:
a first switch element having one end connected to the load apparatus;
a second switch element having one end connected to the other end of the first switch element;
a detection circuit configured to detect an input signal including a voltage at the one end of the second switch element and a voltage at the other end of the second switch element, the input signal being a differential signal;
a first conversion circuit configured to convert the input signal into a first signal having a frequency according to a first clock signal;
a first electromagnetic field coupler having a first terminal and a second terminal, and configured to transmit the first signal received at the first terminal to the second terminal as a second signal via a first isolation element including a capacitance;
a second conversion circuit configured to convert the second signal into an output signal having a frequency according to the input signal based on the first clock signal; and
a first charge and discharge circuit configured to charge or discharge the capacitance of the first electromagnetic field coupler from at least one of the first terminal and the second terminal in response to a voltage of a direct current component of the first signal fluctuating, to suppress a fluctuation of a voltage of a direct current component of the second signal.

Clause 18. The power converter according to clause 17, further comprising a control circuit configured to control driving of the first switch element and the second switch element based on the output signal.

Clause 19. The power converter according to clause 18, wherein the control circuit generates a control signal indicating timings of turn-on and turn-off of the first switch element and the second switch element,
the power converter further comprising a drive circuit configured to generate a drive signal for driving the first switch element and the second switch element based on the control signal.

### Clause 20. A Signal Transmission Method Comprising:

converting an input signal into a first signal having a frequency according to a first clock signal, the input signal being a differential signal; transmitting the first signal as a second signal via a first isolation element including a capacitance;
converting the second signal into an output signal having a frequency according to the input signal based on the first clock signal; and
charging or discharging the capacitance when a voltage of a direct current component of the first signal fluctuates, to suppress a fluctuation of a voltage of a direct current component of the second signal.

1. An electronic circuitry comprising:
a first conversion circuit configured to convert an input signal into a first signal having a frequency according to a first clock signal, the input signal being a differential signal;
a first electromagnetic field coupler having a first terminal and a second terminal, and configured to transmit the first signal received at the first terminal to the second terminal as a second signal via a first isolation element including a capacitance;
a second conversion circuit configured to convert the second signal into an output signal having a frequency according to the input signal based on the first clock signal; and
a first charge and discharge circuit configured to charge or discharge the capacitance of the first electromagnetic field coupler from at least one of the first terminal and the second terminal in response to a voltage of a direct current component of the first signal fluctuating, to suppress a fluctuation of a voltage of a direct current component of the second signal.

2. The electronic circuitry according to claim 1, further comprising: a first detection circuit configured to measure the first signal or the second signal to detect the voltage of the direct current component of the first signal or the second signal, wherein the first charge and discharge circuit charges or discharges the capacitance of the first electromagnetic field coupler based on the voltage of the direct current component detected by the first detection circuit.

3. The electronic circuitry according to claim 2, wherein the first charge and discharge circuit
performs charging when the voltage of the direct current component detected by the first detection circuit is less than a first reference voltage,
performs discharging when the voltage of the direct current component is greater than a second reference voltage, and
performs neither charging nor discharging when the voltage of the direct current component is greater than or equal to the first reference voltage and less than or equal to the second reference voltage.

4. The electronic circuitry according to claim 3, wherein the first detection circuit includes:
a first comparator configured to compare the voltage of the direct current component detected by the first detection circuit with the first reference voltage to generate a first comparison result signal; and
a second comparator configured to compare the voltage of the direct current component detected by the first detection circuit with the second reference voltage to generate a second comparison result signal,
wherein the first charge and discharge circuit performs the charging or the discharging based on the first comparison result signal and the second comparison result signal.

5. The electronic circuitry according to claim 3, wherein the first reference voltage is a sum of a reference potential of the first signal or the second signal and a first predetermined value, and
the second reference voltage is a sum of the reference potential and a second predetermined value larger than the first predetermined value.

6. The electronic circuitry according to claim 1, wherein the input signal is a voltage signal across both terminals of a switch element controlled according to a control signal, and
the first charge and discharge circuit performs the charging or the discharging based on the control signal.

7. The electronic circuitry according to claim 6, wherein the first charge and discharge circuit performs the charging for a first time period in response to a timing at which the control signal indicates turn-on of the switch element, and performs the discharging for a second time period in response to a timing at which the control signal indicates turn-off of the switch element.

8. The electronic circuitry according to claim 1, further comprising: a clock generation circuit configured to generate the first clock signal, wherein the first conversion circuit converts the input signal into the first signal based on the first clock signal generated by the clock generation circuit,
the electronic circuitry further comprising: a second electromagnetic field coupler having a third terminal and a fourth terminal, and configured to transmit the first clock signal received at the third terminal to the fourth terminal as a second clock signal via a second isolation element including a capacitance;
the second conversion circuit converts the second signal into the output signal based on the second clock signal; and
the electronic circuitry further comprising: a second charge and discharge circuit configured to charge or discharge the capacitance of the second electromagnetic field coupler from at least one of the third terminal and the fourth terminal in response to a voltage of a direct current component of the first clock signal fluctuating, to suppress a fluctuation of a voltage of a direct current component of the second clock signal.

9. The electronic circuitry according to claim 8, further comprising: a second detection circuit configured to measure the first clock signal or the second clock signal to detect the voltage of the direct current component of the first clock signal or the second clock signal,
wherein the second charge and discharge circuit charges or discharges the capacitance of the second electromagnetic field coupler based on the voltage of the direct current component detected by the second detection circuit.

10. The electronic circuitry according to claim 9, wherein the second charge and discharge circuit
performs charging when the voltage of the direct current component detected by the second detection circuit is less than a first reference voltage,
performs discharging when the voltage of the direct current component is greater than a second reference voltage, and
performs neither charging nor discharging when the voltage of the direct current component is greater than or equal to the first reference voltage and less than or equal to the second reference voltage.

11. The electronic circuitry according to claim 10, wherein the second detection circuit includes:
a first comparator configured to compare the voltage of the direct current component detected by the second detection circuit with the first reference voltage to generate a first comparison result signal; and
a second comparator configured to compare the voltage of the direct current component detected by the second detection circuit with the second reference voltage to generate a second comparison result signal,
wherein the second charge and discharge circuit performs the charging or the discharging based on the first comparison result signal and the second comparison result signal.

12. The electronic circuitry according to claim 10, wherein the first reference voltage is a sum of a reference potential of the first clock signal or the second clock signal and a first predetermined value, and
the second reference voltage is a sum of the reference potential and a second predetermined value larger than the first predetermined value.

13. The electronic circuitry according to claim 8, wherein the input signal is a voltage signal across both terminals of a switch element controlled according to a control signal, and the second charge and discharge circuit performs the charging or the discharging based on the control signal.

14. The electronic circuitry according to claim 13, wherein the second charge and discharge circuit performs the charging for a first time period in response to a timing at which the control signal indicates turn-on of the switch element, and performs the discharging for a second time period in response to a timing at which the control signal indicates turn-off of the switch element.

15. The electronic circuitry according to claim 1, further comprising:
a first protection circuit connected to the first terminal of the first electromagnetic field coupler and configured to bypass an overvoltage from outside to a power supply potential or a reference potential; and
a second protection circuit connected to the second terminal of the first electromagnetic field coupler and configured to bypass an overvoltage from outside to a power supply potential or a reference potential.

16. The electronic circuitry according to claim 1, wherein the first charge and discharge circuit includes:
one or more switches or one or more current sources, connected between a power supply potential and a first signal line transmitting the first signal or a second signal line transmitting the second signal; and
one or more switches or one or more current sources, connected between a reference potential and the first signal line or the second signal line.

17. A power converter for supplying electric power to a load apparatus, comprising:
a first switch element having one end connected to the load apparatus;
a second switch element having one end connected to the other end of the first switch element;
a detection circuit configured to detect an input signal including a voltage at the one end of the second switch element and a voltage at the other end of the second switch element, the input signal being a differential signal;
a first conversion circuit configured to convert the input signal into a first signal having a frequency according to a first clock signal;
a first electromagnetic field coupler having a first terminal and a second terminal, and configured to transmit the first signal received at the first terminal to the second terminal as a second signal via a first isolation element including a capacitance;
a second conversion circuit configured to convert the second signal into an output signal having a frequency according to the input signal based on the first clock signal; and
a first charge and discharge circuit configured to charge or discharge the capacitance of the first electromagnetic field coupler from at least one of the first terminal and the second terminal in response to a voltage of a direct current component of the first signal fluctuating, to suppress a fluctuation of a voltage of a direct current component of the second signal.

18. The power converter according to claim 17, further comprising a control circuit configured to control driving of the first switch element and the second switch element based on the output signal.

19. The power converter according to claim 18, wherein the control circuit generates a control signal indicating timings of turn-on and turn-off of the first switch element and the second switch element,
the power converter further comprising a drive circuit configured to generate a drive signal for driving the first switch element and the second switch element based on the control signal.

20. A signal transmission method comprising:
converting an input signal into a first signal having a frequency according to a first clock signal, the input signal being a differential signal;
transmitting the first signal as a second signal via a first isolation element including a capacitance;
converting the second signal into an output signal having a frequency according to the input signal based on the first clock signal; and
charging or discharging the capacitance when a voltage of a direct current component of the first signal fluctuates, to suppress a fluctuation of a voltage of a direct current component of the second signal.
